(19) United States
(12) Patent Application Publication
(10) Pub. No.: US 2016/0013770 A1
(43) Pub. Date: Jan. 14, 2016

(54) CAPACITANCE DEVICE, RESONANCE CIRCUIT, AND ELECTRONIC APPARATUS

(71) Applicant: DEXERIALS CORPORATION, Shinagawa-ku, Tokyo (JP)

(72) Inventors: Noritaka SATO, Utsunomiya-shi, Tochigi (JP); Masayoshi KANNO, Utsunomiya-shi, Tochigi (JP)

(73) Assignee: Dexerials Corporation, Shinagawa-ku, Tokyo (JP)

(21) Appl. No.: 14/770,884

(22) PCT Filed: Feb. 17, 2014
(86) PCT No.: PCT/JP2014/053598

§ 371 Date: Aug. 27, 2015

(30) Foreign Application Priority Data
Feb. 28, 2013 (JP) 2013-038749

(51) Int. Cl. H03H 7/01; H01G 4/38; H01G 4/236; H01F 38/14; H01G 4/30; H01G 4/012

(52) U.S. Cl. CPC H03H 9/02; H01G 4/306; H01G 4/38; H01G 4/012; H01G 4/236; H01F 38/14; H01F 2038/146

(57) ABSTRACT

The present disclosure is to improve electric characteristics in a capacitance device (device) including capacitors connected in series in a direction in which internal electrodes are laminated. Three capacitors are formed by dielectric layers (3) and four internal electrodes (30 to 33) laminated via the dielectric layers (3). The internal electrodes (30 to 33) each have an electrode body forming a capacitance, and centers of gravity of these electrode bodies are aligned on an axis formed by a straight line extending in the lamination direction. A device includes two variable capacitance units (40 and 41) each including the capacitors connected in series in the lamination direction, and external terminals formed on lateral surfaces of a variable capacitance device body (2). The axes of the variable capacitance units (40 and 41) are arranged in parallel with each other. A current flows in opposite directions in the two adjacent capacitance units.

### TECHNICAL FIELD

The present disclosure relates to a capacitance device, a resonant circuit, and an electronic apparatus, and particularly to a capacitance device including a plurality of capacitors connected in series in a direction in which internal electrodes are laminated, and a resonant circuit and an electronic apparatus using such a capacitance device. The present disclosure is based on and claims the priority of Japanese Patent Application No. 2013038749 filed in Japan on Feb. 28, 2013, which is herein incorporated by reference.

### BACKGROUND

As disclosed in Patent Literature 1, a variable capacitance device including a plurality of variable capacitance capacitors connected in series in a direction in which internal electrodes are laminated has been proposed. According to the technique disclosed in Patent Literature 1, the internal electrodes forming the variable capacitance capacitors are laminated via dielectric layers, and this configuration allows a reduction in the number of internal electrodes and a wider flexibility in design of the electrodes and the capacitance value.

### CITATION LIST

### Patent Literature

PTL 1: JP2011119482A

### SUMMARY

### Technical Problem

In the variable capacitance device disclosed in Patent Literature 1, internal stresses occur due to contraction of the dielectric layers at the time of sintering. However, the shapes of the internal electrodes on each layer are determined suitably by the capacitance and do not take the internal stresses into account. Furthermore, since, in the variable capacitance device disclosed in Patent Literature 1, the areas of the internal electrodes forming the variable capacitance capacitors connected in series are increased or decreased, each electrode located between adjacent variable capacitance capacitors connected in series has a portion that does not form any capacitor. Such portions of the electrodes pose the problem of an excessive increase in electrode resistance.

Meanwhile, by increasing the number of lamination in the direction in which the electrodes are laminated, the number of series capacitors may be increased, and variations of the composite device may be increased. Increasing the number of lamination also leads to improved pressure resistance while the capacitance is increased by thinned dielectric layers.

However, simply increasing the number of lamination adversely lengthens a physical distance between an electrode laminated on the uppermost layer and an electrode laminated on the lowermost layer and increases Equivalent Series Inductance (ESL), resulting in deterioration of the characteristics especially in use at high frequencies. Furthermore, although the dielectric constants of the dielectrics per unit area may be improved by fixing the internal stresses occurring at the time of sintering (residual stresses), different residual stresses occurring in different layers will cause variation in characteristics of different capacitances formed by the corresponding laminated electrodes.

In view of the above, the present disclosure is to increase, in a capacitance device including a plurality of capacitors connected in series in a direction in which internal electrodes are laminated, variations in connection configuration of the built-in capacitors, thereby improving the electric characteristics.

### Solution to Problem

A capacitance device according to one of embodiments of one aspect of the present disclosure includes two or more capacitance blocks each including one or more capacitance units. Each capacitance unit includes: a capacitance element body, which includes two or more capacitors formed by dielectric layers and three or more internal electrodes laminated via the dielectric layers, the three or more internal electrodes each having an electrode body forming a capacitance, centers of gravity of the electrode bodies being aligned on an axis formed by a straight line extending in a direction in which the internal electrodes are laminated, and the two or more capacitors being connected in series in the lamination direction; and external terminals formed on lateral surfaces of the capacitance element body and electrically connected to the electrode bodies forming the capacitances. The one or more capacitance units included in each capacitance block are arranged on the axis. The axes of the two or more capacitance blocks are arranged in parallel with each other. A current flows in opposite directions in any two adjacent capacitance units.

A resonant circuit according to one of embodiments of another aspect of the present disclosure includes (i) a capacitance device including two or more capacitance blocks each including one or more capacitance units, and (ii) a resonant coil connected to the capacitance device. Each capacitance unit includes: a capacitance element body, which includes two or more capacitors formed by dielectric layers and three or more internal electrodes laminated via the dielectric layers, the three or more internal electrodes each having an electrode body forming a capacitance, centers of gravity of the electrode bodies being aligned on an axis formed by a straight line extending in a direction in which the internal electrodes are laminated, and the two or more capacitors being connected in series in the lamination direction; and external terminals formed on lateral surfaces of the capacitance element body and electrically connected to the electrode bodies forming the capacitances. The one or more capacitance units included in each capacitance block are arranged on the axis. The axes of the two or more capacitance blocks are arranged in parallel with each other. A current flows in opposite directions in any two adjacent capacitance units.

An electronic apparatus according to one of embodiments of yet another aspect of the present disclosure includes a resonant circuit in which a resonant coil is connected to the capacitance device.

### Advantageous Effects

According to the capacitance device according to the present disclosure, since the internal electrodes, which form the plurality of capacitors connected in series in the lamination direction of the electrodes, are laminated with the centers of gravity thereof being aligned, variation in generated residual stresses is reduced, and variation in characteristics is reduced. Furthermore, since a current flowing along the lamination direction flows in opposite directions in any two adjacent capacitance unit, equivalent series inductance is reduced. Moreover, residual stresses generated during sintering processing in manufacturing are increased, and electric characteristics are improved.

### BRIEF DESCRIPTION OF THE DRAWINGS

In the accompanying drawings:

FIG. 1 is a perspective view of a variable capacitance device according to the first embodiment;

FIG. 2A is a plan view illustrating terminal arrangement of the variable capacitance device according to the first embodiment, FIG. 2B is a sectional view taken along a line A-A in FIG. 2A, and FIG. 2C is an equivalent circuit diagram of a variable capacitance device;

FIG. 3 is an exploded view of the variable capacitance device according to the first embodiment;

FIGS. 4A to 4H each illustrate shapes of a dielectric layer and internal electrodes formed on the dielectric layer included in the variable capacitance device according to the first embodiment, and FIG. 4A is a plan view illustrating the shapes of the first and the fifth internal electrode, FIG. 4B is a front view of the same, FIG. 4C is a plan view illustrating the shapes of the second and the sixth internal electrode, FIG. 4D is a front view of the same, FIG. 4E is a plan view illustrating the shapes of the third and the seventh internal electrode, FIG. 4F is a front view of the same, FIG. 4G is a plan view illustrating the shapes of the fourth and the eighth internal electrode, and FIG. 4H is a front view of the same;

FIGS. 5A to 5C each illustrate a method of use of the variable capacitance device according to the first embodiment, and FIG. 5A illustrates a circuit to be used, and FIGS. 5B and 5C each illustrate directions of a current flowing across the internal electrodes;

FIG. 6A is an equivalent circuit diagram of the variable capacitance device according to a modification of the first embodiment, FIG. 6B is a sectional view illustrating the configuration of the variable capacitance device, and FIG. 6C illustrates directions of a current flowing in the variable capacitance device;

FIG. 7A is an equivalent circuit diagram of the variable capacitance device according to the modification of the first embodiment, FIG. 7B is a sectional view illustrating the configuration of the variable capacitance device, and FIG. 7C illustrates directions of a current flowing in the variable capacitance device;

FIGS. 8A and 8B each illustrate variation in the variable capacitance device according to the modification of the first embodiment;

FIGS. 9A and 9B each illustrate the configuration of a variable capacitance device according to another modification of the first embodiment;

FIGS. 10A to 10E each illustrate variation in formation patterns of internal electrodes included in a variable capacitance device;

FIG. 11 illustrates, in a tabular form, exemplary combinations of arrangement of internal electrodes included in the variable capacitance device according to the first embodiment;

FIG. 12A is a plan view illustrating terminal arrangement of a variable capacitance device according to the second embodiment, FIG. 12B is a sectional view illustrating the configuration of the variable capacitance device, FIG. 12C is a plan view illustrating the shape of an internal electrode, and FIG. 12D is an equivalent circuit diagram of the variable capacitance device;

FIGS. 13A and 13B are each a sectional view of the configuration of a variable capacitance device according to a modification of the second embodiment, illustrating variation in the variable capacitance device;

FIG. 14 is a sectional view illustrating variation in the variable capacitance device according to the modification of the second embodiment;

FIGS. 15A and 15B are each a sectional view illustrating variation in the variable capacitance device according to the modification of the second embodiment;

FIG. 16 is a sectional view illustrating variation in the variable capacitance device according to the modification of the second embodiment;

FIGS. 17A and 17B are each a sectional view illustrating variation in the variable capacitance device according to the modification of the second embodiment;

FIGS. 18A to 18D each illustrate variation in external terminals in the variable capacitance device according to the second embodiment, and FIG. 18A is a perspective view of the variable capacitance device, FIG. 18B is a sectional view illustrating the configuration of the variable capacitance device, FIG. 18C illustrates the shape of an internal electrode, and FIG. 18D is an equivalent circuit diagram of the variable capacitance device;

FIGS. 19A and 19B each illustrate variation in external terminals in the variable capacitance device according to the second embodiment, and FIG. 19A is a perspective view of the variable capacitance device, and FIG. 19B is a sectional view illustrating the configuration of the variable capacitance device;

FIG. 20A is a perspective view of a variable capacitance device according to the third embodiment, FIG. 20B is a sectional view illustrating the configuration of the variable capacitance device, and FIG. 20C is a plan view illustrating shapes of internal electrodes;

FIG. 21 is a perspective view illustrating variation in the variable capacitance device according to the third embodiment;

FIGS. 22A to 22D are each a plan view illustrating shapes of internal electrodes of the variable capacitance device according to the third embodiment;

FIG. 23 is a block diagram illustrating an exemplary configuration of a contactless communication system using a variable capacitance device;

FIG. 24 is a block diagram illustrating a main portion of a resonant circuit; and

FIG. 25 is a block diagram illustrating an exemplary configuration of a contactless charging system using a variable capacitance device.

### DETAILED DESCRIPTION

Exemplary embodiments of a capacitance device according to the present disclosure, and a resonant circuit and an electronic apparatus using the capacitance device will be described in detail below with reference to the drawings. The embodiments will be described in the following order. In the following embodiments, variable capacitance devices whose capacitance values change in response to voltages applied thereto are described as examples. However, the present disclosure is not limited to the exemplary embodiments detailed below.

1. First Embodiment: Exemplary Configuration in Which Two Variable Capacitance Units, Which Each Include Three Capacitors Connected in Series, are Arranged in Parallel
1-1 Configuration of Variable Capacitance Device
1-2 Manufacturing Method
1-3 Configuration and Operation of Circuit
2. Modification of First Embodiment: Exemplary Configuration in Which Two Variable Capacitance Blocks, Which Each Include Laminated Identical Variable Capacitance Units, Arranged in Parallel
3. Another Modification of First Embodiment: Exemplary Configuration in Which Electrode is Used in Common by Variable Capacitance Units Laminated Adjacent to Each Other in Single Variable Capacitance Block
4. Second Embodiment: Exemplary Configuration in Which Electrode is Used in Common by Adjacent Variable Capacitance Blocks
5. Modification of Second Embodiment: Exemplary Configuration in Which Plurality of Electrodes are Used in Common by Adjacent Variable Capacitance Blocks
6. Third Embodiment
7. Detailed Examples of Contactless Communication System and Contactless Charging System

### 1. First Embodiment

### 1-1. Configuration of Variable Capacitance Device

In the description below, a direction in which later-described internal electrodes are laminated is defined as a z direction, a direction extending along a long side of a variable capacitance device 1 that is orthogonal to the lamination direction is defined as an x direction, and a direction extending along a short side of the variable capacitance device 1 is defined as a y direction. Furthermore, one of x-y surfaces of the variable capacitance device 1 is defined as an “upper surface” and the other x-y surface of the variable capacitance device 1 is defined as a “lower surface”, and any surfaces that are perpendicular to the upper and the lower surface are defined as “lateral surfaces.”

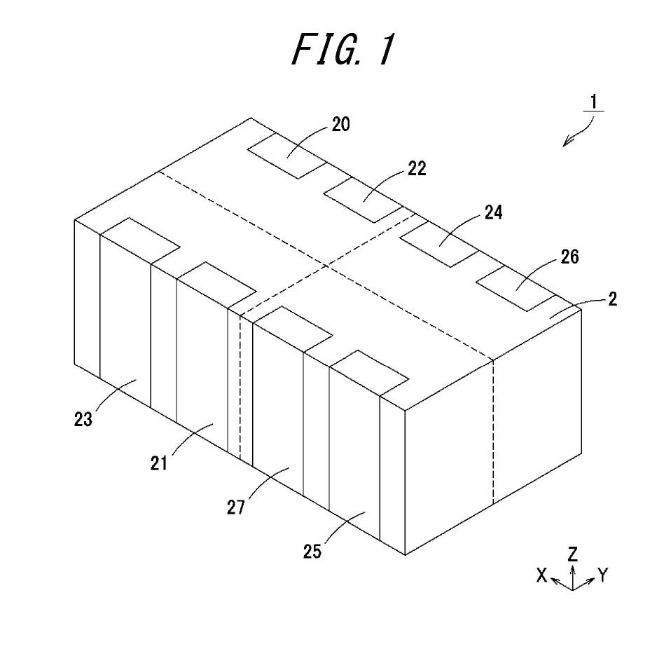

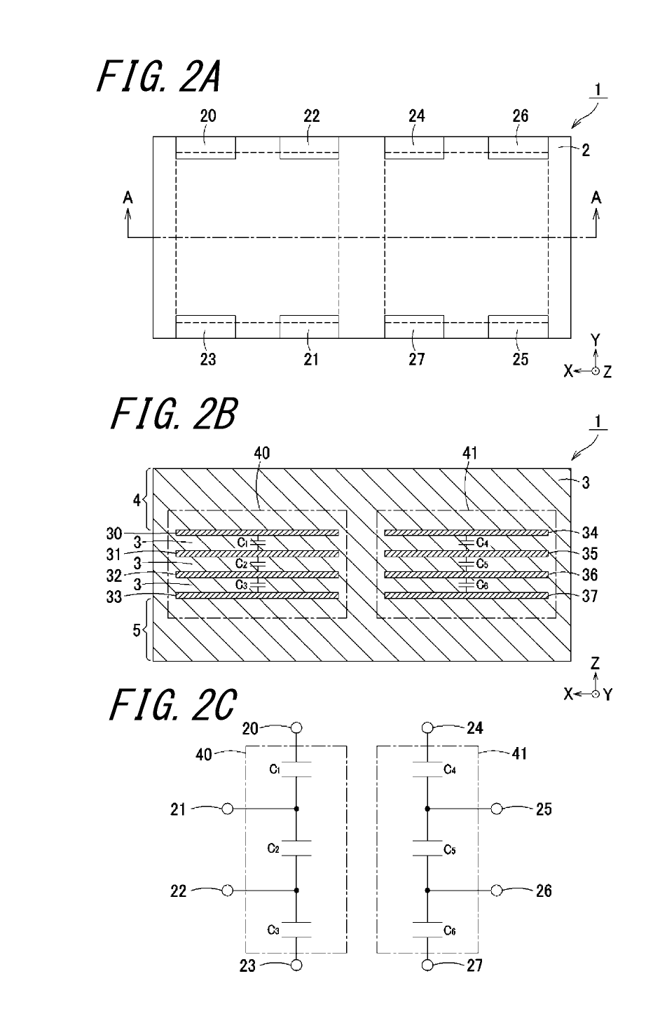

As illustrated in FIG. 1, the variable capacitance device 1 according to the first embodiment of the present disclosure includes a substantially cubic variable capacitance device body 2 and the first to the eighth external terminal 20 to 27 formed on lateral surfaces (x-z planes) extending along long sides of the variable capacitance device body 2. As illustrated in FIG. 2A, the first to the eighth external terminal 20 to 27 are provided to extend across the upper surface and the lower surface (x-y planes) of the variable capacitance device body 2.

As illustrated in FIG. 2B, in the variable capacitance device 1, dielectric layers 3 and eight internal electrodes formed on the dielectric layers 3 are laminated. The eight internal electrodes are called the first to the eighth internal electrode 30 to 37.

The variable capacitance device 1 according to the first embodiment includes the first variable capacitance unit 40 and the second variable capacitance unit 41.

The first variable capacitance unit 40 includes the first internal electrode 30, the second internal electrode 31, the third internal electrode 32, and the fourth internal electrode 33 which are laminated via the dielectric layers 3 in the stated order in the z direction. The first and the second internal electrode 30 and 31 form the first capacitor C1, the second and the third internal electrode 31 and 32 form the second capacitor C2, and the third and the fourth internal electrode form the third capacitor C3. The first to the fourth internal electrode 30 to 33 respectively include the first to the fourth electrode body 30a to 33a that have the same shape and that have the centers of gravity aligned on a single straight line. The variable capacitance unit as used herein below refers to the one including laminated internal electrodes having the same shape unless otherwise specified. Herein, the internal electrodes having the same shape encompass those having a shape rotated 180 degrees on the x-y plane and an inverted (mirror image) shape.

Similarly, the second variable capacitance unit 41 includes the fifth internal electrode 34, the sixth internal electrode 35, the seventh internal electrode 36, and the eighth internal electrode 37 which are laminated via the dielectric layers 3 in the stated order in the z direction. The fifth and the sixth internal electrode 34 and 35 form the fourth capacitor C4, the sixth and the seventh internal electrode 35 and 36 form the fifth capacitor C5, and the seventh and the eighth internal electrode 36 and 37 form the sixth capacitor C6. The fifth to the eighth internal electrode 34 to 37 also have the same shape and have the centers of gravity aligned on a single straight line.

In the exemplary configuration according to the first embodiment, as illustrated in FIG. 2C, the variable capacitance device 1 includes two variable capacitance units each including three series capacitors.

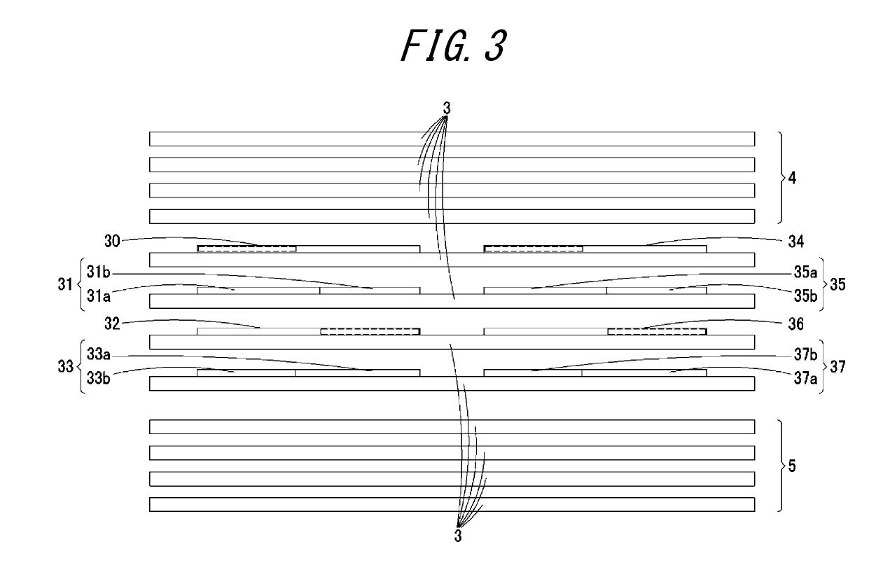

FIG. 3 is an exploded view of the variable capacitance device body 2 before being sintered. The variable capacitance device body 2 include the dielectric layers 3 configured by predetermined dielectrics in the form of sheets, and the first and the fifth internal electrode 30 and 34 laminated on one surface of one of the dielectric layers 3, the second and the sixth internal electrode 31 and 35 laminated on one surface of another one of the dielectric layers 3, the third and the seventh internal electrode 32 and 36 laminated on one surface of yet another one of the dielectric layers 3, and the fourth and the eighth internal electrode 33 and 37 laminated on one surface of yet another one of the dielectric layers 3 in the z direction. Furthermore, in a portion of the variable capacitance device body 2 located above the first and the fifth internal electrode 30 and 34 in the z direction, other some of the dielectric layers 3 are laminated to form an upper dielectric layer 4, and in a portion of the variable capacitance device body 2 located below the fourth and the eighth internal electrode 33 and 37, yet other some of the dielectric layers 3 are laminated to form a lower dielectric layer 5.

The first and the fifth internal electrode 30 and 34 are formed on the same dielectric layer 3, and accordingly, formed on the same plane (x-y plane).The second and the sixth internal electrode 31 and 35 are also formed on the same plane and are arranged in parallel with the first and the fifth internal electrode 30 and 34 at a distance of the thickness of the corresponding dielectric layer 3 from the first and the fifth internal electrode 30 and 34 in the z direction. Similarly, the third and the seventh internal electrode 32 and 36, and the fourth and the eighth internal electrode 33 and 37 are arranged in parallel at a distance of the thickness of the corresponding dielectric layer 3. It is to be noted that the thicknesses of the dielectric layers 3 might change after the variable capacitance device body 2 is sintered.

The upper and the lower dielectric layer 4 and 5 are provided to reinforce mechanical strength of the variable capacitance device body 2.

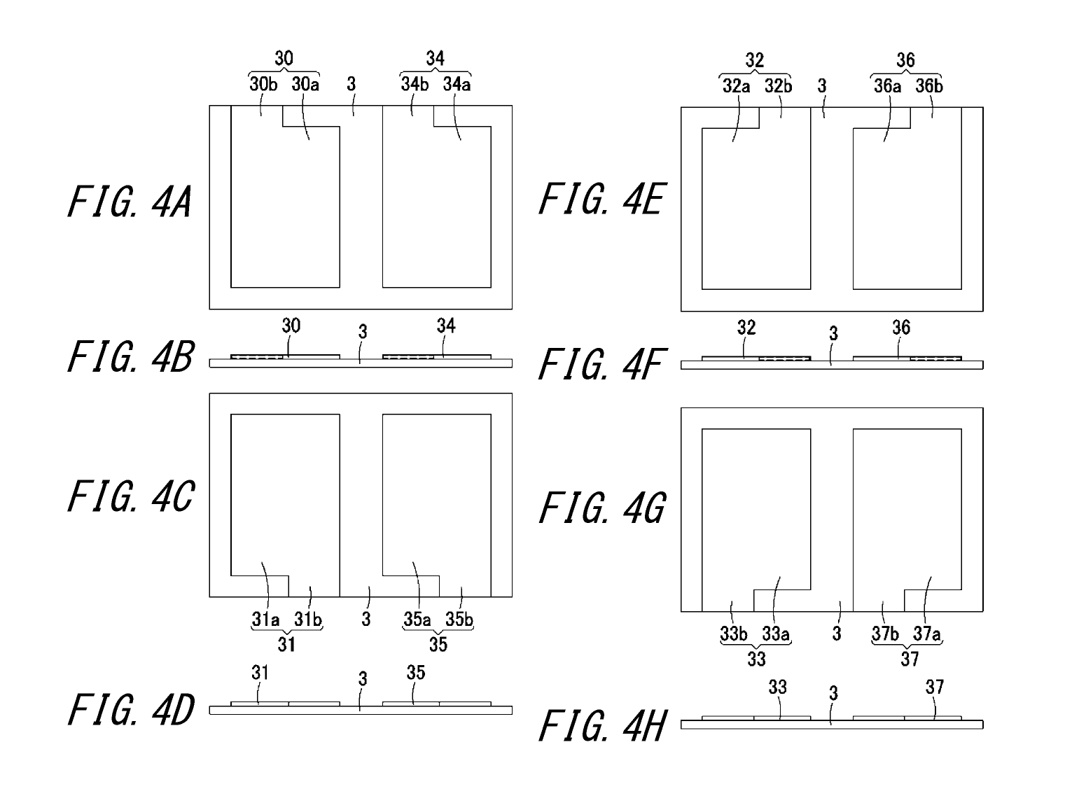

FIGS. 4A to 4H illustrate the shapes of the first to the eighth internal electrode 30 to 37 formed on the dielectric layers 3.

As illustrated in FIGS. 4A and 4B, on one surface of one of the dielectric layers 3 shaped in sheets, the first and the fifth internal electrode 30 and 34 are formed. The first internal electrode 30 includes the first electrode body 30a and the first connection electrode 30b, and the fifth internal electrode 34 includes the fifth electrode body 34a and the fifth connection electrode 34b.

The dielectric layers 3 are configured by using a ferroelectric material to form variable capacitance capacitors whose capacitances change in response to voltages applied across the electrodes. The ferroelectric material may include an ionic crystal material and may be electrically polarized as a result of displacement of positive and negative ions. Examples of the ferroelectric material include barium titanate (BaTiO₃), potassium niobate (KNbO₃), lead titanate (PbTiO₃), and lead zirconate titanate (PZT).

As the ferroelectric material, the one that exhibits electronic polarization may also be used. In this ferroelectric material, an electric dipole moment occurs when a positive charge and a negative charge are separated, which results in polarization. One of conventionally known examples of such a material is a rare-earth iron oxide that exhibits strong ferroelectric characteristics by polarization by forming an Fe₂⁺ charge surface and an Fe₃⁺ charge surface. In this system, when the rare-earth element is represented by RE, and the iron group element is represented by TM, materials expressed by the molecular formula (RE)·(TM)₂·O₄ (O: oxygen element) are reported to have a high dielectric constant. Additionally, examples of the rare-earth element include Y, Er, Yb, and Lu (preferably, Y and heavy rare-earth elements), and of the iron group element include Fe, Co, Ni (preferably, Fe). Examples of (RE)·(TM)₂·O₄ include ErFe₂O₄, LuFe₂O₄, and YFe₂O₄.

The first to the eighth internal electrode 30 to 37 may be configured by using a conductive paste including metallic fine powder of, for example, Pd, Pd/Ag, and Ni.

As illustrated in FIGS. 4A and 4B, the first and the fifth electrode body 30a and 34a included in the first and the fifth internal electrode 30 and 34 are configured to have substantially the same rectangular shape on one surface of the same dielectric layer 3 at a predetermined distance from each other in the x direction. The first and the fifth electrode body 30a and 34a are each arranged in a manner such that the short sides extend along the x direction and the long sides extend in parallel with the y direction.

To mitigate the residual stresses remaining after sintering of the variable capacitance device body 2, a dielectric region is left on the periphery of the first and the fifth electrode body 30a and 34a. Accordingly, the sum of the area of the first electrode body 30a and the area of the fifth electrode body 34a is less than the area of the surface of the dielectric layer 3 on which these electrode bodies 30a and 34a are formed. At this time, the dielectric region on the periphery of the first and the fifth electrode body 30a and 34a is preferably formed to have an area by which residual stresses occurring on the periphery of the first and the fifth connection electrode 30b and 34b at the time of sintering of the variable capacitance device body 2 would not be affected to mitigate the residual stresses. Furthermore, from the viewpoint of reducing Equivalent Series Resistance (hereinafter, abbreviated as ESR) of each capacitor as much as possible, the dielectric region is preferably formed to have a narrow (short) portion near the first and the fifth connection electrode 30b and 34b.

The first and the fifth connection electrode 30b and 34b are respectively formed to be connected to short sides of the first and the fifth electrode body 30a and 34a extending along the x direction, with an end surface of each of the first and the fifth connection electrode 30b and 34b being exposed at a lateral surface of the variable capacitance device body 2. Furthremore, although from the viewpoint of reducing ESR of each capacitor, the first and the fifth connection electrode 30b and 34b preferably have large widths, the residual stresses occurring on the periphery of the first and the fifth connection electrode 30b and 34b after sintering of the variable capacitance device body 2 also needs to be considered. Accordingly, the first and the fifth connection electrode 30b and 34b are each preferably formed to have a width by which the residual stresses occurring in the area of the first and the fifth electrode body 30a and 34a would not be affected.

The residual stresses herein refer to stresses that originate due to a difference in contraction coefficient between an electrode material and a dielectric material during sintering process in manufacturing of the variable capacitance device body 2. Accordingly, to prevent the residual stresses occurring on the periphery of the first and the fifth connection electrode 30b and 34b from affecting the residual stresses occurring in the first and the fifth electrode body 30a and 34a, the first and the fifth connection electrode 30b and 34b are preferably formed to have areas that are sufficiently less than the areas of the first and the fifth electrode body 30a and 34a. In the exemplary configuration of the present embodiment, the widths of the first and the fifth connection electrode 30b and 34b in the x direction are sufficiently less than the widths of the first and the fifth electrode body 30a and 34a in the x direction.

For example, to achieve the areas that are sufficiently small to prevent the residual stresses occurring on the periphery of the first and the fifth connection electrode 30b and 34b from affecting the residual stresses occurring in the area of the first and the fifth electrode body 30a and 34a, the widths of the first and the fifth connection electrode 30b and 34b in the x direction are preferably one quarter or less of the widths of the first and the fifth electrode body 30a and 34a in the x direction, respectively.

The end surfaces of the first and the fifth connection electrode 30b and 34b that are exposed to the lateral surface of the variable capacitance device body 2 are electrically connected respectively to the first and the fifth external terminals 20 and 24.

As illustrated in FIGS. 4C and 4D, similarly to the first and the fifth internal electrode 30 and 34, the second and the sixth internal electrode 31 and 35 are formed on one surface of the same dielectric layer 3 at a predetermined distance from each other in the x direction. The second internal electrode 31 includes the second electrode body 31a and the second connection electrode 31b, and the sixth internal electrode 35 includes the sixth electrode body 35a and the sixth connection electrode 35b. The second and the sixth internal electrode 31 and 35 have shapes obtained by rotating 180 degrees the patterns of the first and the fifth internal electrode 30 and 34.

The end surfaces of the second and the sixth connection electrode 30b and 33b that are exposed to a lateral surface of the variable capacitance device body 2 are electrically connected respectively to the second and the sixth external terminals 20 and 25.

As illustrated in FIGS. 4E and 4F, the third internal electrode 32 includes the third electrode body 32a and the third connection electrode 32b, and the seventh internal electrode 36 includes the seventh electrode body 36a and the seventh connection electrode 36b.

The third and the seventh electrode body 32a and 36a have shapes that are the same as those of the first and the fifth electrode body 30a and 34a and the second and the sixth electrode body 31a and 35a. The third and the seventh connection electrode 32b and 36b have shapes that are identical to those of the first and the fifth connection electrode 30b and 34b. However, the third and the seventh connection electrode 32b and 36b are connected to the third and the seventh electrode body 32a and 36a at different positions, so that the third and the seventh connection electrode 32b and 36b are extracted to external terminals through different positions.

The end surfaces of the third and the seventh connection electrode 32b and 36b that are exposed to a lateral surface of the variable capacitance device body 2 are electrically connected respectively to the third and the seventh external terminals 22 and 26.

The fourth and the eighth internal electrode 33 and 37 have shapes obtained by rotating 180 degrees the patterns of the third and the seventh internal electrode 32 and 36.

The end surfaces of the fourth and the eighth connection electrode 33b and 37b that are exposed to a lateral surface of the variable capacitance device body 2 are electrically connected respectively to the fourth and the eighth external terminals 23 and 27.

Meanwhile, in some of the electrodes through which an alternate current does not flow to an external terminal, there is no problem even if electrical resistance of the connection electrodes is high, and therefore, the widths of the connection electrodes may be formed to be small relative to those of the electrode bodies. For example, the widths of the connection electrodes 31b, 32b, 35b, and 36b may be small. On the other hand, the other electrodes through which an alternate current flows still need to be designed to have smallest possible ESR as described earlier.

Herein, as illustrated in FIG. 3, the internal electrodes are laminated in a manner such that the centers of gravity of the first to the fourth internal electrode 30 to 33 are aligned on a single straight line and that the centers of gravity of the fifth to the eighth internal electrode 34 to 37 are aligned on another single straight line. Such arrangement with the centers of gravity of the internal electrodes being aligned reduces variation in residual stresses resulting from internal stresses occurring at the time of sintering of the variable capacitance device body 2, thereby reducing variation in characteristics of the capacitors.

Additionally, although in the above description the first to the fourth internal electrode and the fifth to the eighth internal electrode have the same shape, needless to say, the first to the fourth internal electrode and the fifth to the eighth internal electrode may have different shapes, that is to say, the capacitors included in the variable capacitance units located adjacent in the x-y plane may have different capacitances.

### 1-2. Manufacturing Method

A description is give of an exemplary manufacturing method of the variable capacitance device 1 with the above configuration. Firstly, dielectric sheets made from a desired dielectric material are prepared. The dielectric sheets are used to configure the dielectric layers 3 of the variable capacitance device body 2 and are each shaped with a thickness of, for example, approximately 2.5 μm. The dielectric sheets may be each formed by applying a predetermined thickness of the dielectric material in the form of paste onto a film such as a polyethylene terephthalate (PET) film. Masks provided with openings corresponding to regions in which the first to the eighth internal electrodes 30 to 37 illustrated in FIGS. 4A to 4H are to be formed are prepared. At this time, for the first and the fifth internal electrode 30 and 34 and the second and the sixth internal electrode 31 and 35, a single mask may be used by rotating the mask 180 degrees. Similary, for the third and the seventh internal electrode 32 and 36 and the fourth and the eighth internal electrode 33 and 37, a single mask may be used by rotating the mask 180 degrees. Alternatively, instead of rotating the mask 180 degrees for printing, the dielectric sheets may be rotated 180 degrees when being laminated as described later.

Subsequently, the conductive paste including metallic fine powder of, for example, Pt, Pd, Pd/Ag, Ni, and Ni alloy in the form of paste is prepared. The prepared paste is applied (silk printed) onto one surface of each of some of the dielectric sheets via the prepared mask. The above processes are used to prepare the dielectric sheet on one surface of which the first and the fifth internal electrode 30 and 34 are formed, the dielectric sheet on one surface of which the second and the sixth internal electrode 31 and 35 are formed, the dielectric sheet on one surface of which the third and the seventh internal electrode 32 and 36 are formed, and the dielectric sheet on one surface of which the fourth and the eighth internal electrode 33 and 37 are formed. At this time, the centers, i.e., the centers of gravity, of the electrode bodies of the electrodes are aligned throughout the layers.

Some dielectric sheets formed on films such as PET films and not printed with electrodes are peeled off from the films and laminated in advance. Then, the dielectric sheets with the first to the eighth internal electrodes 30 to 37 formed on films such as PET films are peeled off from the films and laminated in a desired order, with the surfaces of the dielectric sheets on which the electrodes are printed facing to the same direction. At this time, the dielectric sheets are laminated in a manner such that the sides of the first to the fourth electrode body 30a to 33a are aligned in the x direction and in the y direction, with the centers (centers of gravity) of these electrode bodies 30a to 33a being in alignment in the z direction, and that the sides of the fifth to the eighth electrode body 34a to 37a are aligned in the x direction and in the y direction, with the centers (centers of gravity) of these electrode bodies 34a to 37a being in alignment in the z direction. Then, to this laminated body, some additional dielectric sheets on which no electrodes are printed are further laminated and compression-bonded.

The compression-bonded members are sintered at a high temperature in a reducing atmosphere to integrate the dielectric sheets and the electrodes configured by using the conductive paste. Thus, the variable capacitance device body 2 is fabricated. Subsequently, the first to the eighth external terminal 20 to 27 are attached to predetermined positions on the lateral surfaces of the variable capacitance device body 2. The reason for using the reducing atmosphere at the time of sintering is that oxidization of the internal electrodes needs to be prevented. As oxidization of the internal electrodes proceeds, the equivalent series resistance increases, and the internal electrodes are prevented from serving the intended functions. This prevents formation of capacitors. However, an excessively reducing atmosphere will reduce the dielectric material to a semiconductor. As the degree of reduction of the dielectric material increases, a leakage current increases, and the quality (Q) factors of the capacitors are decreased. Voltage proof performance of the capacitors is also decreased.

### 1-3. Configuration and Operation of Circuit

As illustrated in FIG. 2C, the variable capacitance device 1 is a composite capacitor circuit element including the first variable capacitance unit 40 and the second variable capacitance unit 41. The first and the second variable capacitance unit 40 and 41 respectively include C1 to C3 connected in series and C4 to C6 connected in series.

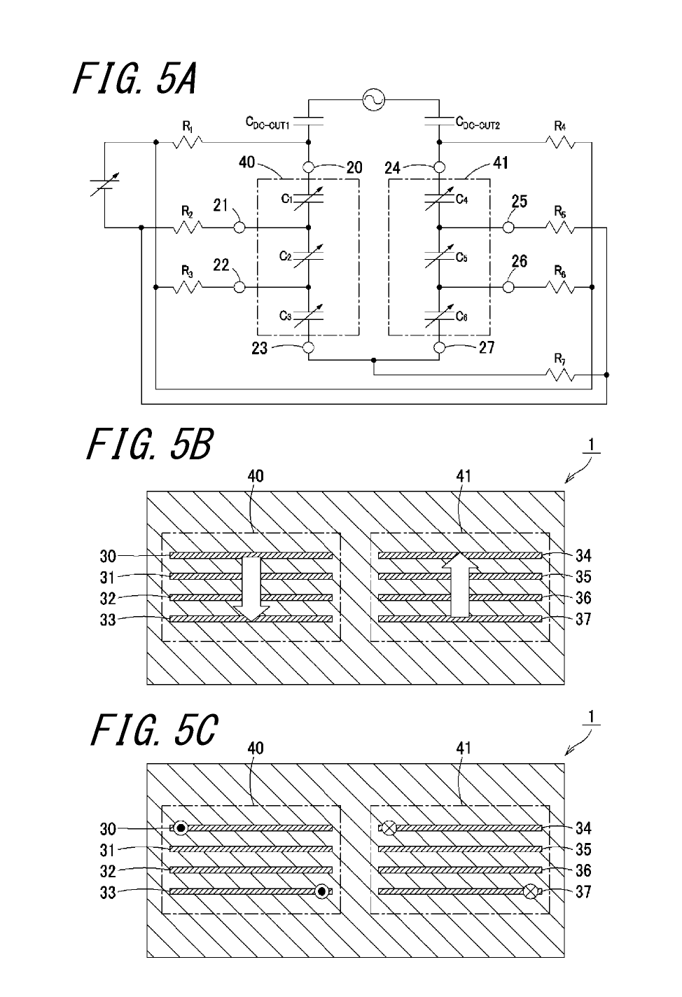

Herein, as illustrated in FIG. 5A, by connecting a signal source between the first external terminal 20 and the third external terminal 24, and by connecting the fourth external terminal 23 to the eighth external terminal 27 by using external wiring, a series connection circuit of C1 to C6 is configured. When an alternate current signal is generated from the signal source, as illustrated in FIG. 5B, at a certain moment, the current flowing along the lamination direction (z direction) from C1 through C6 flows in one direction from C1 through C3 and flows in a direction opposite to the one direction from C4 through C6, as indicated by arrows in the figure. Accordingly, as illustrated in FIG. 5B, the direction in which the current flows in the first variable capacitance unit 40 is opposite to the direction in which the current flows in the second variable capacitance unit 41 located adjacent to the first variable capacitance unit 40, and the magnetic fields generated by the current flowing in opposite directions serve to cancel out each other. As a result, ESL is reduced.

Although in the above description ESL is reduced by cancelling out the magnetic fields generated on the x-y plane by the current flowing along the lamination direction (z direction), ESL may be further reduced by cancelling out magnetic fields generated by the current flowing along the internal electrodes, that is to say, flowing along the x-y plane. In the circuit configuration of FIG. 5A, the current flowing along the surfaces of the internal electrodes (along the x-z plane) flows to the first and the fifth external terminal 20 and 24, which are an input and an output terminal to which the signal source is connected, and to the fourth and the eighth external terminal 23 and 27, which provide an input and an output for the external wiring externally connected to establish the series connection. As illustrated in FIG. 5C, the alternate current flowing along the surfaces of the internal electrodes generate the magnetic fields. The current flows in opposite directions (at a certain moment, a black dot symbol represents a direction from backward to forward in the figure, and an x symbol represents a direction from forward to backward in the figure) in adjacent internal electrodes, such as the first internal electrode 30 and the fifth internal electrode 34, and the fourth internal electrode 33 and the eighth internal electrode 37, that are located on the same plane. By the current thus flowing in directions by which the magnetic fields are cancelled out in the same x-y plane, ESL is further reduced.

In this way, by establishing the connection by which the current flows in opposite directions in the first and the second variable capacitance unit 40 and 41, the variable capacitance device 1 is operated with a reduced ESL. Furthermore, by using electrodes located on the same plane as the input and the output terminal for the alternate current and letting the current flow in opposite directions in these terminals, ESL is further reduced.

Although in the above description each variable capacitance unit includes three capacitors connected in series, the number of capacitors included in each variable capacitance unit may be two, four, or even more. However, the variable capacitance unit as used herein below is assumed to include three capacitors connected in series.

The capacitance of the variable capacitance device 1, that is to say, capacitances of the capacitors C1 to C3 and C6 to C4 may be changed in response to direct current voltages applied to the capacitors. Changes in values of the direct current voltages cause changes in capacitances of the capacitors C1 to C3 and C6 to C4, namely, a change in the capacitance of the variable capacitance device 1. A single source may be used in common for the direct current voltages to be applied to the capacitors as illustrated in FIG. 5A. At this time, the alternate current needs to be prevented, as much as possible, from flowing through a connecting line of the direct current voltages. To this end, as illustrated in FIG. 5A, resistances R1 to R7 are connected so that the direct current voltages are applied to ends of the capacitors via the resistances R1 to R7. At this time, an impedance (resistance value) of the resistances R1 to R7 is set to be sufficiently greater than an impedance of the variable capacitance device 1, which corresponds to an impedance between the external terminal 20 and the external terminal 24 when the external terminal 23 is connected to the external terminal 27. The impedance of the resistances R1 to R7 is set to be preferably five times or more, more preferably 10 times or more, and even more preferably 50 times or more. Additionally, a capacitor C_{dc-cut1} and a capacitor C_{dc-cut2} are provided to prevent the direct current voltages from entering the alternate current signal. A capacitance of these capacitors are set to be sufficiently greater than the capacitance of the variable capacitance device 1. The capacitance of these capacitors is set to be preferably five times or more, more preferably 10 times or more, and even more preferably 50 times or more. Furthermore, a Q factor of these capacitors is set to be greater, as much as possible, than a Q factor of the variable capacitance device 1. The Q factor of these capacitors is set to be preferably five times or more, more preferably 10 times or more, and even more preferably 50 times or more.

### 2. Modification of First Embodiment

### [Two Variable Capacitance Blocks Each Including Two Variable Capacitance Units]

The variable capacitance device 1 according to the first embodiment of the present disclosure provides various modifications.

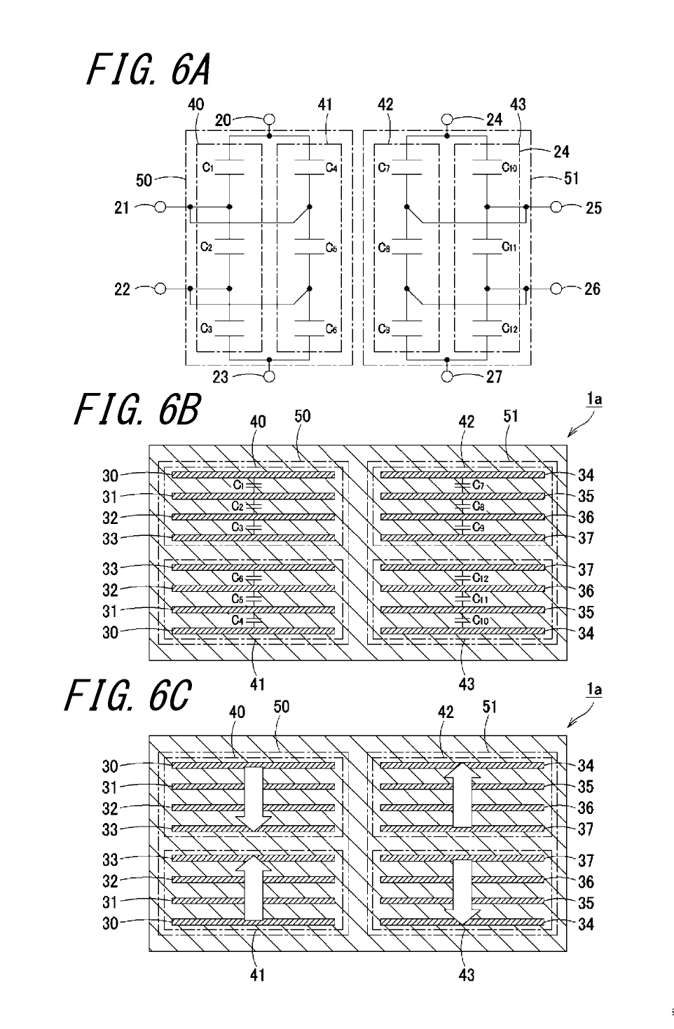

As illustrated in FIG. 6A, a variable capacitance device 1a includes the first variable capacitance block 50, which includes the first variable capacitance unit 40 and the second variable capacitance unit 41, and the second variable capacitance block 51, which includes the third variable capacitance unit 42 and the fourth variable capacitance unit 43.

As illustrated in FIG. 6B, the first variable capacitance unit 40 includes the first to the fourth internal electrode 30 to 33 which are laminated via the dielectric layers 3. The second variable capacitance unit 41 includes the fourth to the first internal electrode 33 to 30 which are laminated via the dielectric layers 3. Thus, in the first and the second variable capacitance unit 40 and 41, the internal electrodes are laminated in opposite orders. The first to the fourth internal electrode 30 to 33 have the same shapes as those illustrated in FIGS. 4A to 4H.

The first to the fourth internal electrode 30 to 33 respectively include the first to the fourth electrode body 30a to 33a and the first to the fourth connection electrode 30b to 33b, and the first connection electrode 30b of the first variable capacitance unit 40 is electrically connected to the first connection electrode 30b of the second variable capacitance unit 41 by the first external terminal 20.

Similarly, the second to the fourth connection electrode 31b to 33b of the first variable capacitance unit 40 are electrically connected to the second to the fourth connection electrode 31b to 33b of the second variable capacitance unit 41 by the second to the fourth external terminal 21 to 23, respectively.

Thus, the first and the second variable capacitance unit 40 and 41 included in the first variable capacitance block 50 are connected in parallel. Herein, an axis that the centers of gravity of the internal electrodes included in the first variable capacitance unit 40 form is aligned on a single straight line with an axis that those of the internal electrodes included in the second variable capacitance unit 41 form. In the variable capacitance block as used herein below, all the axes that the centers of gravity of the respective internal electrodes in the variable capacitance units included in the variable capacitance block form are assumed to be aligned on a single straight line. That is to say, the centers of gravity of the internal electrodes included in a single variable capacitance block are aligned on the same axis.

The third variable capacitance unit 42 includes the fifth to the eighth internal electrode 34 to 37 which are laminated via the dielectric layers 3. The fourth variable capacitance unit 43 includes the eighth to the fifth internal electrode 37 to 34 which are laminated via the dielectric layers 3. Thus, in the third and the fourth variable capacitance unit 42 and 43, the internal electrodes are laminated in opposite orders. The fifth to the eighth internal electrode 34 to 37 have the same shapes as those illustrated in FIGS. 4A to 4H.

The fifth to the eighth internal electrode 34 to 37 respectively include the fifth to the eighth connection electrode 34b to 37b, and the fifth connection electrode 34b of the third variable capacitance unit 42 is electrically connected to the fifth connection electrode 34b of the fourth variable capacitance unit 43 by the fifth external terminal 24.

Similarly, the sixth to the eighth connection electrode 35b to 37b of the third variable capacitance unit 42 are electrically connected to the sixth to the eighth connection electrode 35b to 37b of the fourth variable capacitance unit 43 by the sixth to the eighth external terminal 25 to 27, respectively.

Thus, the third and the fourth variable capacitance unit 42 and 43 included in the second variable capacitance block 51 are connected in parallel.

Hence, the variable capacitance device la according to a modification of the first embodiment includes two variable capacitance blocks each including two variable capacitance units connected in parallel, each variable capacitance unit including three series capacitors.

The first internal electrode 30 located on the uppermost layer in the first variable capacitance unit 40 is electrically connected to the first internal electrode 30 located on the lowermost layer in the second variable capacitance unit 41. Accordingly, similarly to the case of FIG. 5A, by connecting a signal source to each of the first external terminal 20 and the fifth external terminal 24 and by connecting the fourth external terminal 23 and the eighth external terminal 27, as illustrated in FIG. 6C, at a certain moment, an alternate current flows in opposite directions in the first and the second variable capacitance unit 40 and 41 as indicated by arrows in the figure. Similarly, the alternate current flows in opposite directions in the third and the fourth variable capacitance unit 42 and 43. Furthermore, the alternate current flows in opposite directions in the first variable capacitance unit 40 and the third variable capacitance unit 42 located adjacent to the first variable capacitance unit 40 in the x direction. In this way, the direction in which the alternate current flows in one unit is opposite to the direction in which the alternate current flows in other units located adjacent to the one unit in the z direction and in the x direction, and the magnetic fields generated by the alternate current flowing through these units are cancelled out by each other. As a result, ESL is reduced.

ESL may be further reduced by causing the alternate current to flow in opposite directions in internal electrodes located on the same x-y plane, in other words, by causing the alternate current to be inputted and outputted to and from the corresponding external terminals in opposite directions. Furthermore, regarding the magnetic fields generated by the current flowing along the direction (x-z plane) of the surfaces of the internal electrodes, ESL may be further reduced by causing the current to flow in opposite directions in two adjacent internal electrodes.

### [Two Variable Capacitance Blocks Each Including Three Variable Capacitance Units]

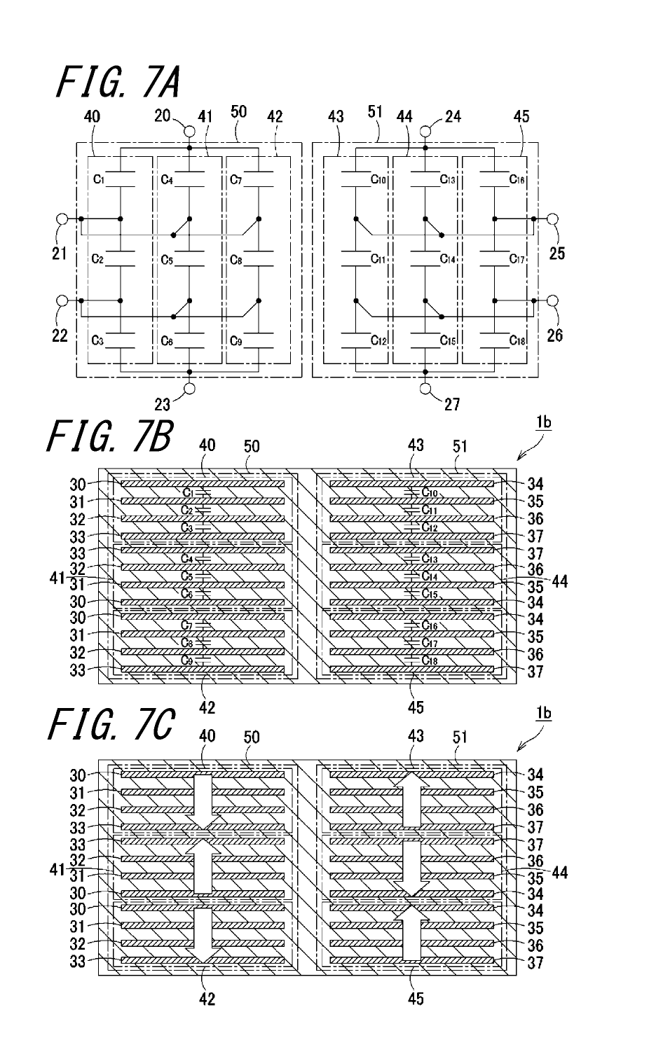

As illustrated in FIG. 7A, a variable capacitor device 1b including two variable capacitance blocks each including three variable capacitance units connected in parallel, each variable capacitance unit including three series capacitors, may be also configured.

The variable capacitance device 1b includes the first variable capacitance block 50 and the second variable capacitance block 51.

The first variable capacitance block 50 includes the first variable capacitance unit 40, the second variable capacitance unit 41 laminated below the first variable capacitance unit 40, and the third variable capacitance unit 42 laminated below the second variable capacitance unit 41.

The first variable capacitance unit 40 includes the first to the fourth internal electrode 30 to 33 which are laminated via the dielectric layers 3. The second variable capacitance unit 41 includes the fourth to the first internal electrode 33 to 30 which are laminated via the dielectric layers 3. The third variable capacitance unit 42 includes the first to the fourth internal electrode 30 to 33 which are laminated via the dielectric layers 3. Thus, in any adjacent two of the first to the third variable capacitance unit 40 to 42, the internal electrodes are laminated in opposite orders. The first to the fourth internal electrode 30 to 33 have the same shapes as those illustrated in FIGS. 4A to 4H.

The first internal electrode 30 located on the uppermost layer in the first variable capacitance unit 40, the first internal electrode 30 located on the lowermost layer in the second variable capacitance unit 41, and the first internal electrode 30 located on the uppermost layer in the third variable capacitance unit 42 are extracted from the corresponding first connection electrode 30b, 30b, and 30b and are electrically connected by the first external terminal 20.

Similarly, the second to the fourth internal electrode 31 to 33 in each unit are electrically connected by the second to the fourth external terminal 21 to 23, respectively.

The second variable capacitance block 51 includes the fourth variable capacitance unit 43, the fifth variable capacitance unit 44 laminated below the fourth variable capacitance unit 43, and the sixth variable capacitance unit 45 laminated below the fifth variable capacitance unit 44.

The fourth variable capacitance unit 43 includes the fifth to the eighth internal electrode 34 to 37 which are laminated via the dielectric layers 3. The fifth variable capacitance unit 44 includes the eighth to the fifth internal electrode 37 to 34 which are laminated via the dielectric layers 3. The sixth variable capacitance unit 45 includes the fifth to the eighth internal electrode 34 to 37 which are laminated via the dielectric layers 3. Thus, in any adjacent two of the fourth to the sixth variable capacitance unit 43 to 45, the internal electrodes are laminated in opposite orders. The fifth to the eighth internal electrode 34 to 37 have the same shapes as those illustrated in FIGS. 4A to 4H. The fifth internal electrode 34 located on the uppermost layer in the fourth variable capacitance unit 43, the fifth internal electrode 34 located on the lowermost layer in the fifth variable capacitance unit 44, and the fifth internal electrode 34 located on the uppermost layer in the sixth variable capacitance unit 45 are extracted from the corresponding fifth connection electrode 34b, 34b, and 34b and are electrically connected by the fifth external terminal 24.

Similarly, the sixth to the eighth internal electrode 35 to 37 in each unit are electrically connected by the sixth to the eighth external terminal 25 to 27, respectively.

Similarly to the case of FIG. 5A, by connecting a signal source to each of the first external terminal 20 and the fifth external terminal 24 and by connecting the fourth external terminal 23 and the eighth external terminal 27, as illustrated in FIG. 7C, an alternate current flowing along the lamination direction (z direction) flows in opposite directions in any two adjacent variable capacitance units included in the same variable capacitance block. Furthermore, in the adjacent two variable capacitance blocks, the current flowing along the lamination direction (z direction) flows in opposite directions in any two adjacent variable capacitance units. By the current thus flowing to cancel out the magnetic fields generated by the current flowing along the lamination direction, ESL is reduced. ESL is further reduced on any planes extending in parallel with the x-y plane in the same manner as described above.

Although the above description is directed to a method for reducing ESL when the first and the second variable capacitance block 50 and 51 are connected in series, the ESL reduction effect may also be achieved by using other ways of connection by changing external connection so that the current flows other way around in any adjacent units. For example, by connecting the first external terminal 20 and the eighth external terminal 27, by connecting the fourth external terminal 23 and the fifth external terminal 24 (in cross connection), and by connecting a signal source between the first external terminal 20 and the eighth external terminal 27, parallel connection between the first and the second variable capacitance block 50 and 51 is achieved.

Furthermore, by changing the number of units included in each block, even a greater variety of combinations of variable capacitance device may be achieved.

### 3. Another Modification of First Embodiment

### [Unification of Internal Electrodes in Variable Capacitance Units]

Each variable capacitance unit included in the variable capacitance devices 1, 1a, and 1b described above includes series capacitors configured by using four internal electrodes. However, in capacitance units located adjacent to each other in a single variable capacitance block, there are internal electrodes located on the uppermost layer or the lowermost layer and always having the equal potential. By unifying these internal electrodes, the number of internal electrodes may be reduced.

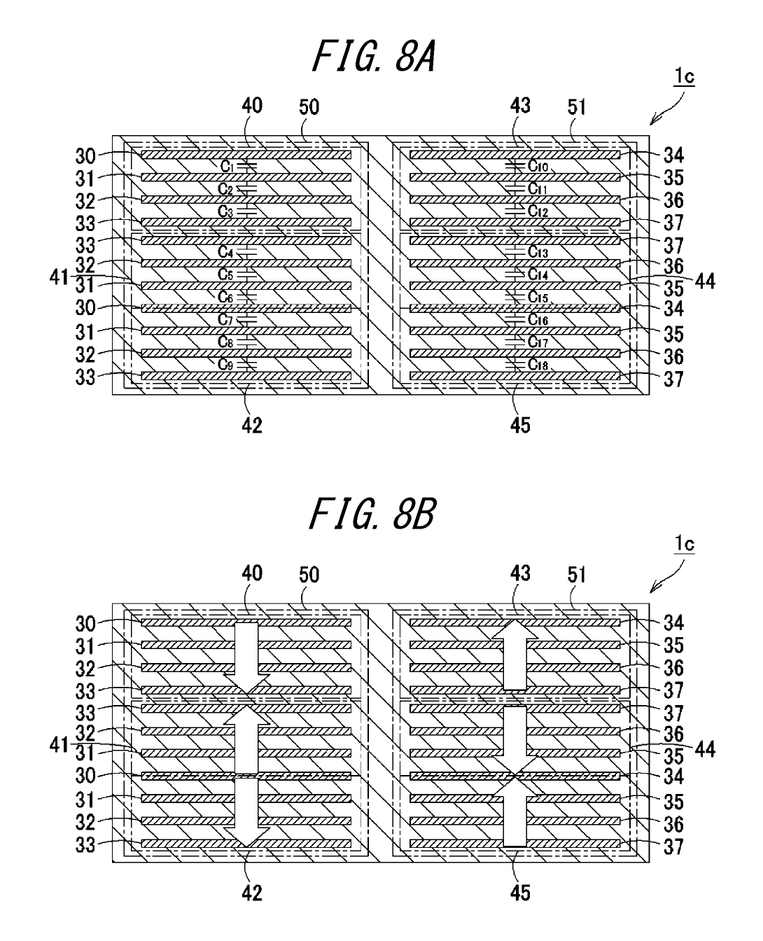

As illustrated in FIGS. 8A and 8B, the variable capacitance device 1c includes the first and the second variable capacitance block 50 and 51 similarly to the variable capacitance device 1b illustrated in FIGS. 7A to 7C, and the first variable capacitance block 50 includes the first to the third variable capacitance unit 40 to 42. Herein, as illustrated in FIG. 7A, the fourth internal electrode 33 forming the lowermost layer in the second variable capacitance unit 41 has a potential equal to that of the fourth internal electrode 33 forming the uppermost layer in the third variable capacitance unit 42. Accordingly, as illustrated in FIG. 8A, by unifying into a single layer the dielectric layers 3 on which the fourth internal electrodes 33 of the second and the third variable capacitance unit 41 and 42 are formed, the two fourth internal electrodes 33 are unified into a single electrode. Similarly, for the second variable capacitance block, by unifying into a single layer the dielectric layers 3 on which the fifth internal electrodes 34 of the fifth and the sixth variable capacitance unit 44 and 45 are formed, the two fifth internal electrodes 34 are unified into a single electrode.

Unifying two internal electrodes and reducing the number of dielectric layers 3 on which the internal electrodes are formed contributes to thinning and weight reduction of the variable capacitance device 1. Doing so also reduces manufacturing man-hours and contributes to a reduction in manufacturing cost.

The variable capacitance device 1c with the above configuration is electrically equivalent to the configuration illustrated in FIGS. 7A to 7C. However, it is to be noted that, since the thickness of the internal electrode is substantially reduced to ½, ESR will be increased, which leads to an increase in direct current loss or the like.

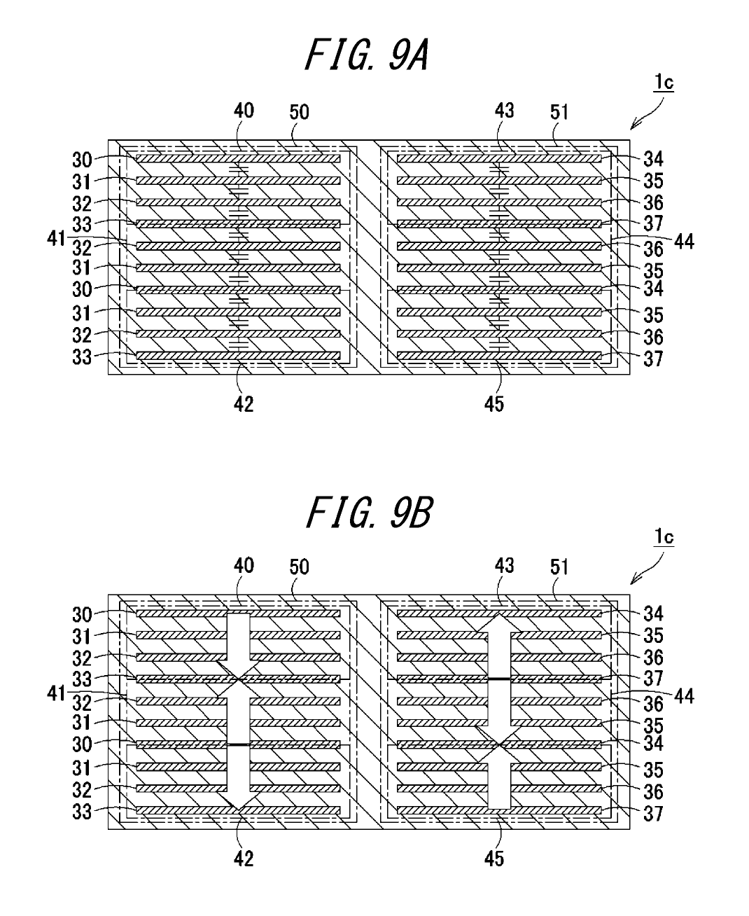

As illustrated in FIG. 9A, by further unifying the fourth internal electrodes 33 included in the first and the second variable capacitance unit 40 and 41 and unifying the eighth internal electrodes 37 included in the fourth and the fifth variable capacitance unit 43 and 44 to reducing the number of dielectric layers 3 on which these internal electrodes are formed into a single layer, the number of dielectric layers 3 is reduced by two layers in total compared to the case illustrated in FIGS. 7A to 7C. Since each variable capacitance unit and each variable capacitance block have the same configurations as in the case illustrated in FIGS. 7A to 7C, as illustrated in FIG. 9B, a current flows in opposite directions in any two adjacent variable capacitance units. As a result, ESL is reduced.

Reducing the number of internal electrodes allows further thinning, weight reduction, and cost reduction. Still, it is to be noted that ESR might be increased.

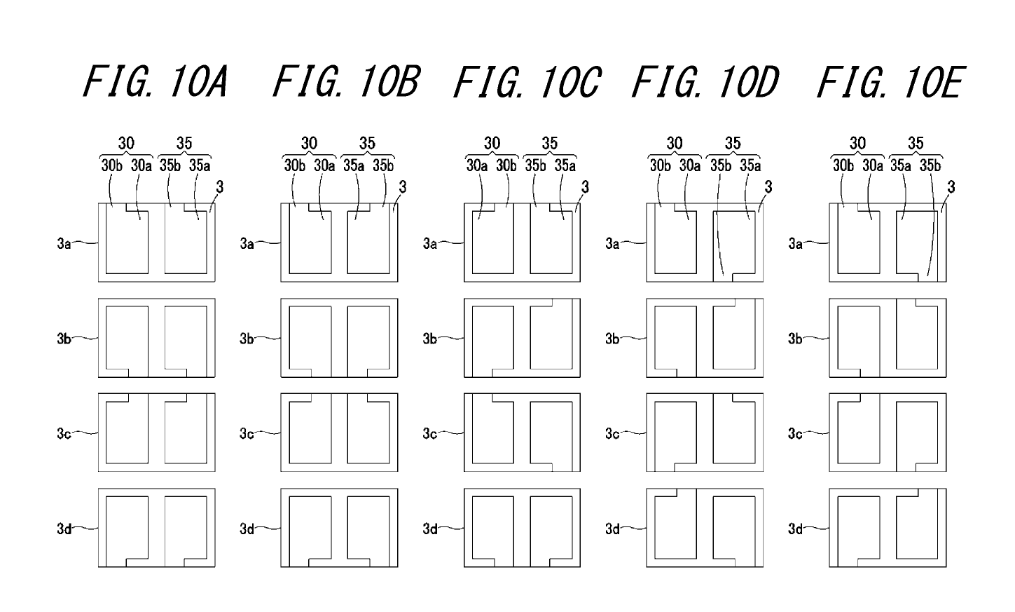

In the aforementioned first embodiment, as illustrated in FIGS. 10A to 10E, positions of formation of four internal electrodes included in a single variable capacitance unit may be varied in some other way.

As described earlier, electrode bodies and connection electrodes included in internal electrodes may be formed by conducting a silk printing process once every some internal electrodes formed on a single layer. Terminal connection in the variable capacitance device may be changed in accordance with the positions in which connection electrodes are formed. In this regard, an increase in types of mask patterns formed and used for the silk printing process leads to an increase in cost, and therefore, the patterns of the internal electrodes to be formed need to be determined in consideration of cost and manufacturing man-hours.

The patterns of the internal electrodes illustrated in FIG. 10A are those used for the aforementioned configuration and are the same as those illustrated in FIG. 4.

In FIGS. 10A to 10E, reference numeral 3a denotes a pattern in which the first and the fifth internal electrode 30 and 34 are formed, reference numeral 3b denotes a pattern in which the second and the sixth internal electrode 31 and 35 are formed, reference numeral 3c denotes a pattern in which the third and the seventh internal electrode 32 and 36 are formed, and reference numeral 3d denotes a pattern in which the fourth and the eighth internal electrode 33 and 37 are formed.

In FIG. 10A, the pattern 3b is identical to the pattern 3a albeit being rotated 180 degrees. The pattern 3d is identical to the pattern 3c albeit being rotated 180 degrees. Accordingly, there are two types of electrode patterns in the case of FIG. 10A.

In FIG. 10B, the pattern 3d is identical to the pattern 3a albeit being rotated 180 degrees. The pattern 3b is identical to the pattern 3c. Accordingly, there are two types of electrode patterns.

In FIG. 10C, the pattern 3d is identical to the pattern 3a albeit being rotated 180 degrees. However, the pattern 3b is an inverted pattern relative to the pattern 3c, and the pattern 3b and the pattern 3c need to be formed individually. Accordingly, there are three types of electrode patterns.

In FIG. 10D, the pattern 3a is identical to the pattern 3d albeit being rotated 180 degrees. The pattern 3b is identical to the pattern 3c albeit being rotated 180 degrees. Accordingly, there are two types of electrode patterns.

In FIG. 10E, the pattern 3a is an inverted pattern relative to the pattern 3d, and the pattern 3b is an inverted pattern relative to the pattern 3c. Accordingly, there are four types of electrode patterns.

Additionally, the way of extracting the electrodes may also be changed in accordance with the order in which the internal electrodes are laminated.

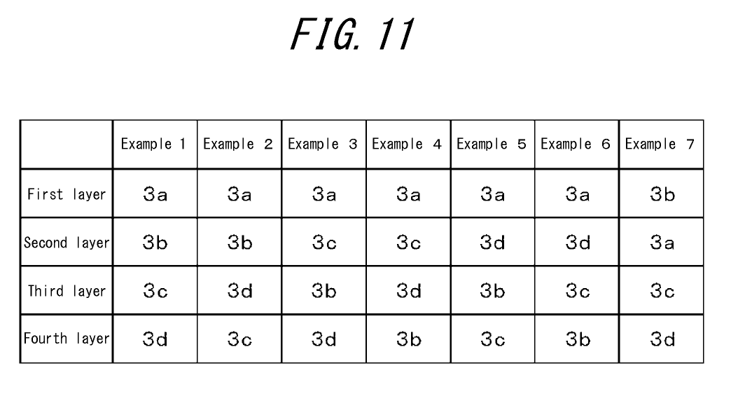

A table illustrated in FIG. 11 indicates how many variations of order of lamination of the internal electrodes are available in combining the aforementioned electrode patterns illustrated in FIG. 10A. As indicated, for example, seven variations of the way of extracting the electrodes are considered. For the cases illustrated in FIGS. 10B to 10E, the ways of extracting the electrodes may be similarly changed.

### 4. Second Embodiment

### [Unification of Internal Electrodes in Variable Capacitance Blocks]

In, for example, FIG. 5A, ESL is reduced by establishing the connection by which a current flowing along the lamination direction (z direction) flows in opposite directions in the first and the second variable capacitance block 50 and 51 and the generated magnetic fields are cancelled out, by serially connecting the first and the second variable capacitance block 50 and 51 by using external wiring. Herein, when the series connection between the first and the second variable capacitance unit 40 and 41 (or, the first and the second variable capacitance block 50 and 51) is internally established in advance, the external wiring pattern may be omitted, and accordingly, packaging density is improved.

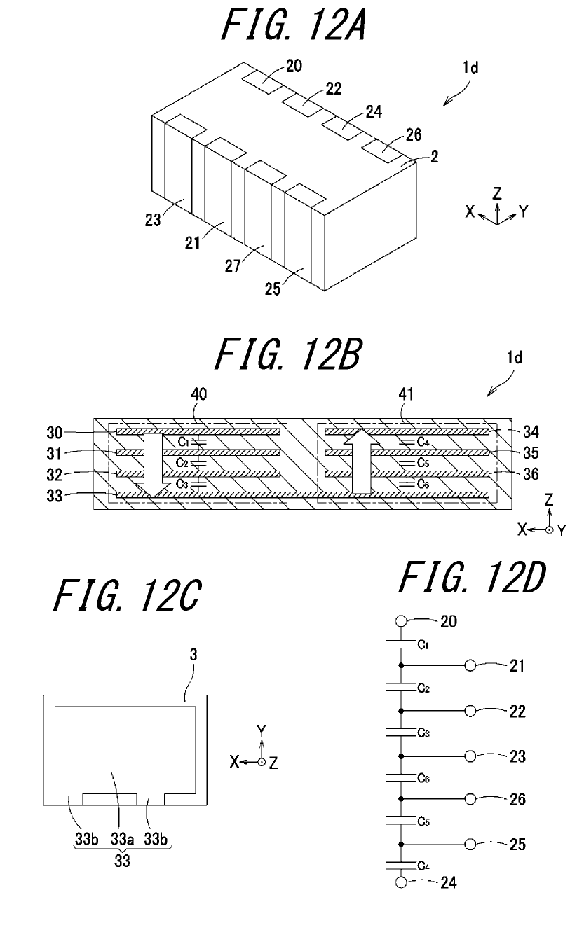

As illustrated in FIG. 12A, a variable capacitance device 1d including the first and the second variable capacitance block 50 and 51 connected in series is configured while compatibility for external terminal arrangement is maintained.

The variable capacitance device 1d according to the second embodiment includes the first variable capacitance unit 40 and the second variable capacitance unit 41.

The first variable capacitance unit 40 includes the first to the fourth internal electrode 30 to 33 laminated via the dielectric layers 3. The capacitor C1 is formed by the first and the second internal electrode 30 and 31 via the corresponding dielectric layer 3, the capacitor C2 is formed by the second and the third internal electrode 31 and 32 via the corresponding dielectric layer 3, and the capacitor C3 is formed by the third and the fourth internal electrode 32 and 33 via the corresponding dielectric layer 3.

The second variable capacitance unit 41 includes the fifth to the seventh internal electrode 34 to 36 laminated via the dielectric layers 3 and the fourth internal electrode 33 laminated below the seventh internal electrode 36 via the dielectric layer 3. The capacitor C4 is formed by the fifth and the sixth internal electrode 34 and 35 via the corresponding dielectric layer 3, the capacitor C5 is formed by the sixth and the seventh internal electrode 35 and 36 via the corresponding dielectric layer 3, and the capacitor C6 is formed by the seventh and the fourth internal electrode 36 and 33 via the corresponding dielectric layer 3. Herein, the single fourth internal electrode 33 serves as both an electrode located on the lowermost layer of the first variable capacitance unit 40 and an electrode located on the lowermost layer of the second variable capacitance unit 41, thereby providing internal connection in replacement of the connection between the fourth external terminal 23 and the eighth external terminal 27 by using external wiring in the variable capacitance device 1 illustrated in FIG. 5A.

The first to the third internal electrode 30 to 32 and the fifth to the seventh internal electrode 34 to 36 are the same as those illustrated in FIGS. 4A to 4F. The first to the third internal electrode 30 to 32 respectively include the first to the third electrode body 30a to 32a and the first to the third connection electrode 30b to 32b, and the fifth to the seventh internal electrode 34 to 36 respectively include the fifth to the seventh electrode body 34a to 36a and the fifth to the seventh connection electrode 34b to 36b. The fourth internal electrode 33 is formed by adding a pattern connecting the two electrode bodies formed on the corresponding dielectric layer 3 illustrated in FIG. 4C. Since an alternate current flows across the above pattern, as illustrated in FIG. 12C, the connection is preferably established with a pattern having a width of the electrode body 33a in the y direction.

With the above configuration, as illustrated in FIG. 12C, a circuit of serially connected six capacitors, namely, the capacitors C1 to C3 connected in series and the capacitors C6 to C4 connected in series, is achieved. By connecting a signal source to the first external terminal 20 and the fifth external terminal 24, a current flowing along the z direction flows in opposite directions in the adjacent units, and the generated magnetic fields are cancelled out by each other. As a result, ESL is reduced. Furthermore, the current also flows in opposite directions along the x-y plane for an input and an output of the first and the fifth external terminals 20 and 24, and as a result, ESL is further reduced. Note that, although in the circuit illustrated in FIG. 5A the external connection through the fourth and the eighth external terminal 23 and 27 contributes to carry the current in opposite directions along the x-y plane, in this example no equivalent contribution to the reduction in ESL is present since the fourth internal electrode and the eighth internal electrode are unified. On the other hand, as far as ESR during use is concerned, the variable capacitance device 1d is more advantageous than the variable capacitance device 1 because of a smaller ESR. The reason is that, in the variable capacitance device 1, that is, the circuit illustrated in FIG. 5A, the electrode body 33a included in the capacitor C3 and the electrode body 36a included in the capacitor C6 are connected through the connection electrode 33b, through the fourth external terminal 23, the external wiring, and the eighth external terminal 27, and through the connection electrode 37b, whereas, in the variable capacitance device 1d the capacitor C3 and the capacitor C6 are directly connected in the x direction of the electrode body 33a.

As illustrated in an equivalent circuit of FIG. 12D, the fourth external terminal 23 is commonly used. Additionally, as illustrated in FIG. 12A, as the fourth external terminal 23, the eighth external terminal used in the variable capacitance device 1 illustrated in FIG. 1 may be replaced by the fourth external terminal 23.

### 5. Modification of Second Embodiment

### [Lamination of Variable Capacitance Units and Unification of Internal Electrodes in Variable Capacitance Blocks]

In the variable capacitance device according to the second embodiment, the variable capacitance units may be laminated in the z direction to form a variable capacitance block including the variable capacitance units connected in parallel.

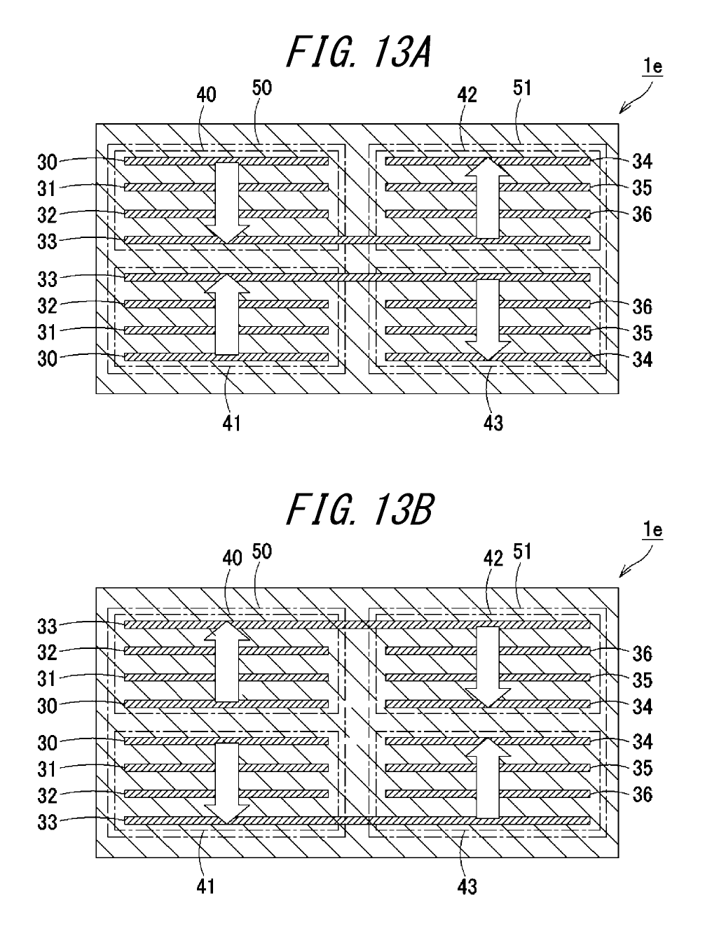

For example, as illustrated in FIG. 13A, a variable capacitance device 1e according to a modification of the second embodiment includes the first variable capacitance block 50, which includes the first variable capacitance unit 40 and the second variable capacitance unit 41, and the second variable capacitance block 51, which includes the third variable capacitance unit 42 and the fourth variable capacitance unit 43.

The first variable capacitance unit 40 includes the first to the fourth internal electrode 30 to 33 which are laminated via the dielectric layers 3. The second variable capacitance unit 41 includes the fourth to the first internal electrode 33 to 30 which are laminated via the dielectric layers 3. Thus, in the first and the second variable capacitance unit 40 and 41, the internal electrodes are laminated in opposite orders. The first to the third internal electrode 30 to 33 have the same shapes as those illustrated in FIGS. 4A to 4H. The fourth internal electrode 33 is the same as that illustrated in FIG. 12C.

The first to the fourth internal electrode 30 to 33 respectively include the first to the fourth connection electrode 30b to 33b, and the first connection electrode 30b of the first variable capacitance unit 40 is electrically connected to the first connection electrode 30b of the second variable capacitance unit 41 by the first external terminal 20.

Similarly, the second to the fourth connection electrode 31b to 33b of the first variable capacitance unit 40 are electrically connected to the second to the fourth connection electrode 31b to 33b of the second variable capacitance unit 41 by the second to the fourth external terminal 21 to 23, respectively.

Thus, the first and the second variable capacitance unit 40 and 41 included in the first variable capacitance block 50 are connected in parallel.

The third variable capacitance unit 42 includes the fifth to the seventh internal electrode 34 to 36 which are laminated via the dielectric layers 3 and also includes the laminated fourth internal electrode 33. The fourth variable capacitance unit 43 includes the seventh to the fifth internal electrode 36 to 34 which are laminated via the dielectric layers 3 and also includes the laminated fourth internal electrode 33. Thus, in the third and the fourth variable capacitance unit 42 and 43, the internal electrodes are laminated in opposite orders. The fifth to the eighth internal electrode 34 to 37 have the same shapes as those illustrated in FIGS. 4A to 4F and FIG. 12C.

The order of lamination of the first to the fourth internal electrodes 30 to 33 and the fifth to the seventh internal electrodes is not limited to the example illustrated in FIG. 13A. As illustrated in FIG. 13B, the order of lamination may be inverted.

As indicated by arrows in each of FIGS. 13A and 13B, an alternate current flowing along the z direction flows in opposite directions in any two adjacent units, and the magnetic fields generated by the alternate current flowing in opposite directions are cancelled out. As a result, ESL is reduced.

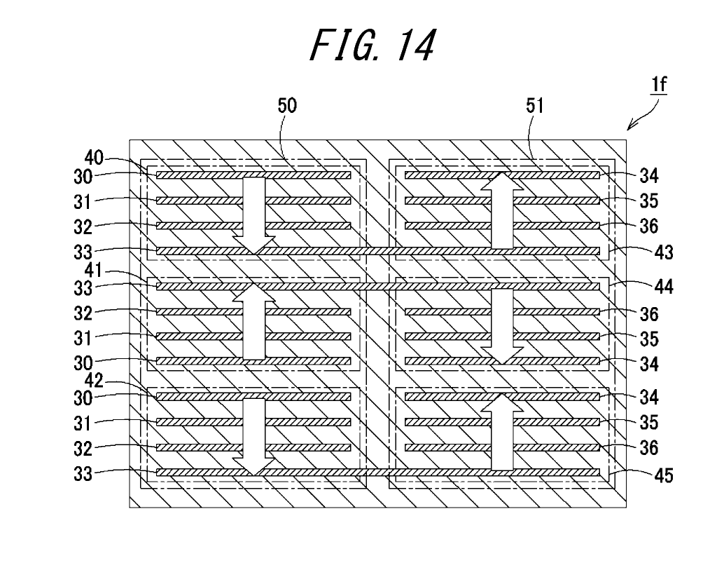

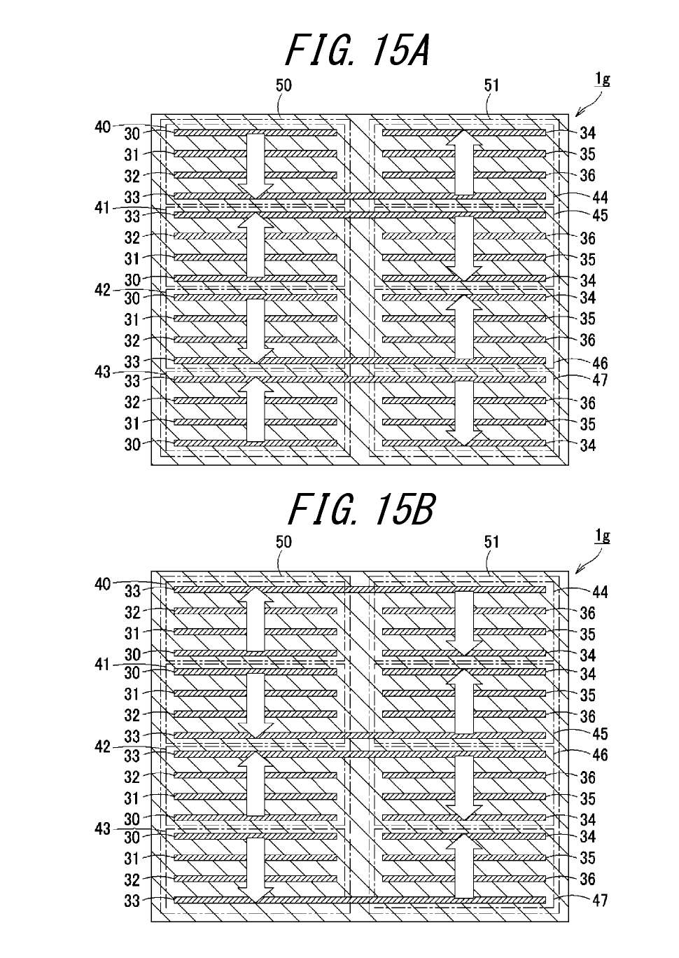

Furthermore, as illustrated in FIGS. 14 and 15, by increasing the number of lamination in the z direction and by connecting the units in parallel, capacitance values of the capacitors may be increased.

In a variable capacitance device 1f illustrated in FIG. 14, the first and the second variable capacitance block 50 and 51 each include three variable capacitance units connected in parallel.

In a variable capacitance device 1g illustrated in FIG. 15A, the first and the second variable capacitance block 50 and 51 each include four variable capacitance units connected in parallel.

FIG. 15B illustrates a variable capacitance device that has the same functionality and performance as the variable capacitance device 1g illustrated in FIG. 15A but includes the variable capacitance units each including the internal electrodes laminated in an inverse order.

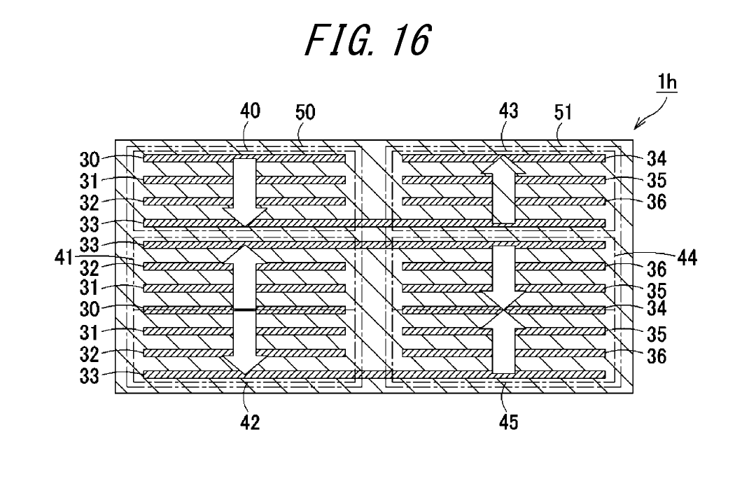

Furthermore, as illustrated in FIG. 16, by unifying internal electrodes located on the uppermost layer and on the lowermost layer in variable capacitance units located adjacent in the lamination direction (z direction), thinning, weight reduction, and cost reduction may be achieved. In a variable capacitance device 1h illustrated in FIG. 16, the first internal electrodes 30 are unified, and the fifth internal electrodes 34 are also unified.

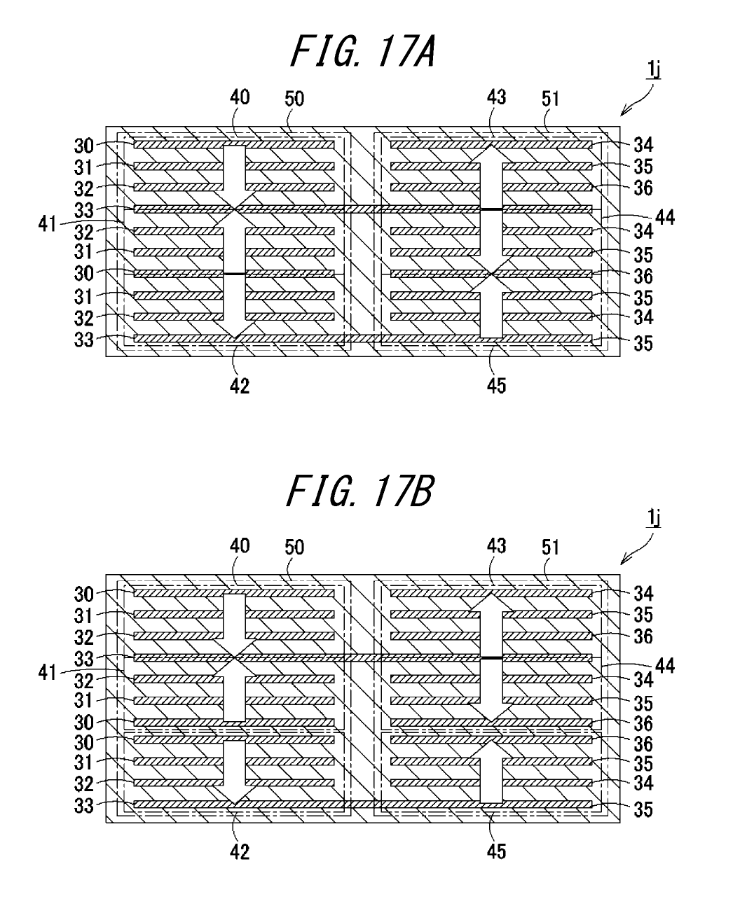

Moreover, as illustrated in FIGS. 17A and 17B, the fourth internal electrodes 33 unified in the first and the second variable capacitance block 50 and 51 may also be unified in units located adjacent in the lamination direction (z direction) in each variable capacitance block. FIG. 17A illustrates an exemplary configuration of a variable capacitance device 1j in which the fourth internal electrodes 33 unified in the two variable capacitance blocks are unified in variable capacitance units located adjacent in the lamination direction (z direction) and in which the first and the fifth internal electrodes 30 and 34 are also unified. FIG. 17B illustrates an exemplary configuration in which only the fourth internal electrodes 33 unified in the two variable capacitance blocks are also unified in the units.

### [Exemplary Variations in External Terminal Arrangement]

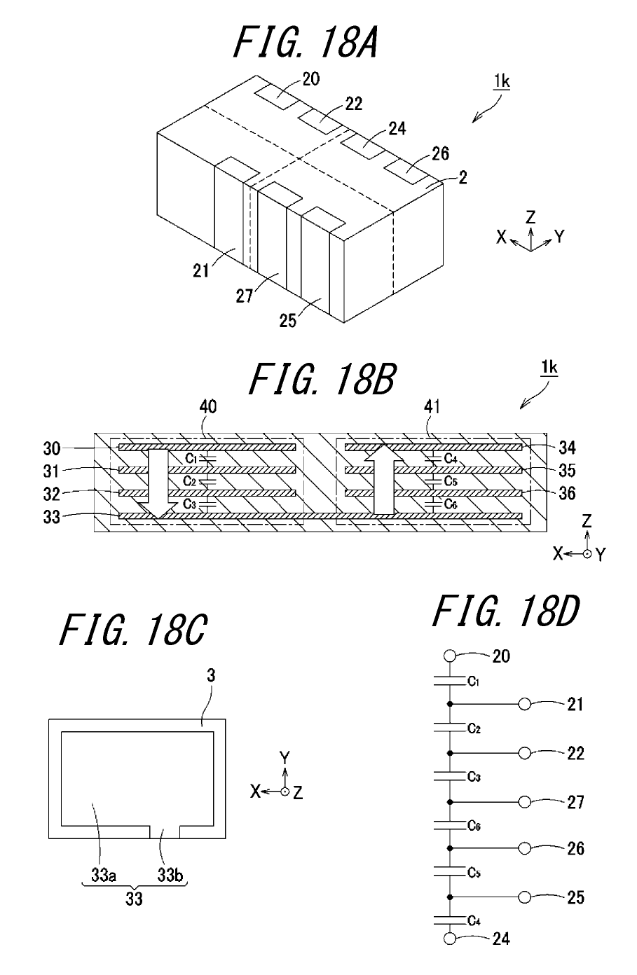

As illustrated in FIGS. 18A and 18B, in a variable capacitance device 1k, differing from external terminal arrangement illustrated in FIG. 12A, of course, a single external terminal may be provided for the internal electrode (fourth internal electrode 33) resulting from unification. As illustrated in FIG. 18C, the variable capacitance device 1k may include only a single fourth connection electrode 33b in the fourth internal electrode 33. Even with this configuration, as illustrated in FIG. 18D, exactly the same circuit configuration as in the case illustrated in FIG. 12C is achieved.

Furthermore, external terminals may be arranged on all the four sides of the variable capacitance device body 2.

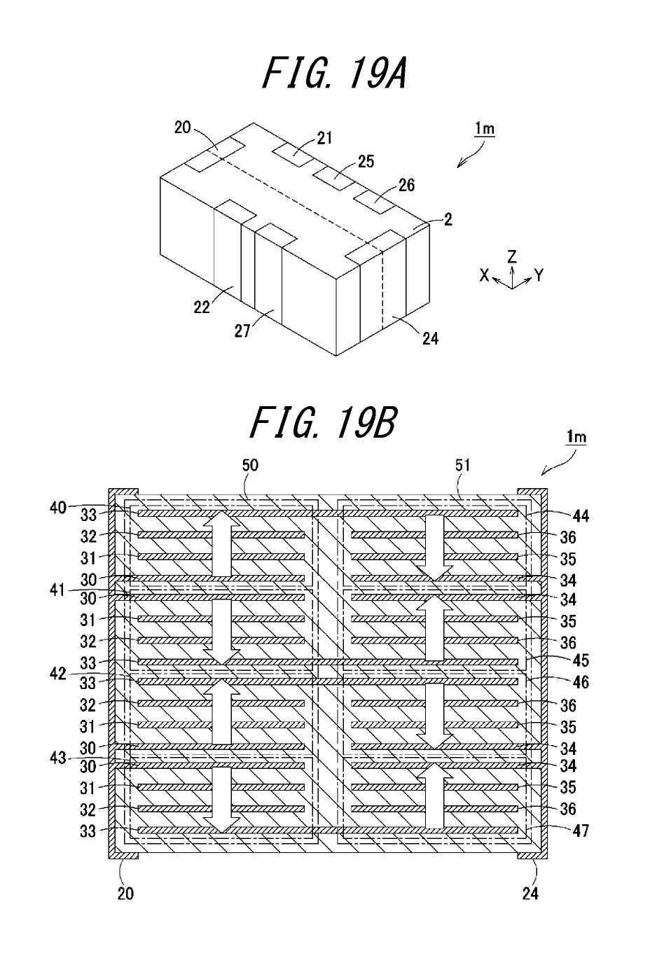

For example, as illustrated in FIGS. 19A and 19B, in a variable capacitance device lm, the first internal electrode 30 and the fifth internal electrode 34 may be arranged on opposing sides that are different from the sides on which the other external terminals are arranged. When a signal source is connected between the first external terminal 20 and the fifth external terminal 24, a primary alternate current flows across the first and the fifth external terminal 20 and 24. When the primary alternate current is presumed to be a large current, one of the sides of the variable capacitance device body 2 may be used for a single external terminal to increase the area of the external terminal. By doing so, connection resistance with an external circuit is reduced. Furthermore, the width of the connection electrode is increased, and as a result, ESR is further reduced.

### 3. Third Embodiment

### [Arrangement of Three or More Variable Capacitance Blocks]

In each of the first and the second embodiment, the variable capacitance device includes two variable capacitance blocks (or variable capacitance units) arranged on the x-y plane. The number of variable capacitance blocks to be arranged is not limited to two and may be three or more.

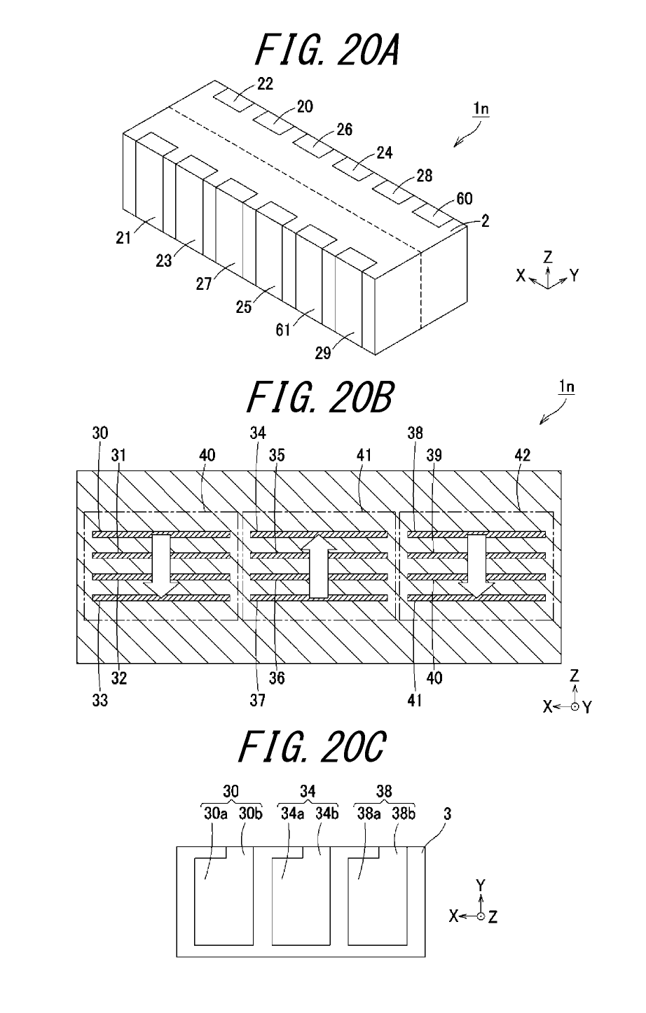

As illustrated in FIGS. 20A to 20C, a variable capacitance device in includes the first variable capacitance unit 40, the second variable capacitance unit 41, and the third variable capacitance unit 42.

The first variable capacitance unit 40 includes the first internal electrode 30, the second internal electrode 31, the third internal electrode 32, and the fourth internal electrode 33 which are laminated via the dielectric layers 3.

The second variable capacitance unit 41 includes the fifth internal electrode 34, the sixth internal electrode 35, the seventh internal electrode 36, and the eighth internal electrode 37 which are laminated via the dielectric layers 3.

The third variable capacitance unit 42 includes the ninth internal electrode 38, the tenth internal electrode 39, the eleventh internal electrode 70, and the twelfth internal electrode 71 which are laminated via the dielectric layers 3.

Similarly to the first and the second embodiment, the first internal electrode 30, the fifth internal electrode 34, and the ninth internal electrode 38 are formed on the same dielectric sheet (FIG. 20C). The other internal electrodes are also arranged in the same way as in, for example, FIG. 4, and a description thereof is omitted.

Additionally, an additional variable capacitance unit (or variable capacitance block) may be added to provide four, five, or more of these.

As the number of variable capacitance units is increased on the x-y plane, an aspect ratio of the variable capacitance device body 2 on the x-y plane is excessively increased, which often leads to variation in internal residual stresses after sintering of the dielectrics. To address this, the variable capacitance units may be arranged extendedly not in the y direction but also in the x direction.

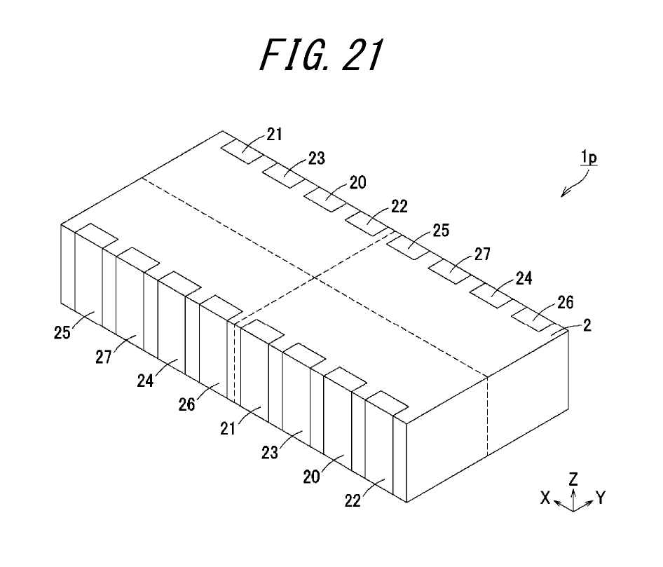

As illustrated in FIG. 21, four variable capacitance units may be arranged on the x-y plane in a rectangular shape, and external terminals of two variable capacitance units may be formed on one side of the variable capacitance device body 2, and external terminals of the other two variable capacitance units may be formed on another side of the variable capacitance device body 2 that opposes to the one side.

In more detail, a variable capacitance device 1p is divided into four portions by lines extending in the x direction and in the y direction and intersecting in the middle of the variable capacitance device body 2. For convenience, an upper left portion is defined as a region (i), an upper right portion is defined as a region (ii), a lower left portion is defined as a region (iii), and a lower right portion is defined as a region (iv). In each region, variable capacitance units are arranged. The variable capacitance units arranged in each unit includes the external terminals on the corresponding side extending along the x direction. In detail, a variable capacitance unit (i) arranged in the region (i) includes, from left, the second external terminal 21, the fourth external terminal 23, the first external terminal 20, and the third external terminal 24, and similarly, a variable capacitance unit (ii) arranged in the region (ii) includes, from left, the sixth external terminal 25, the eighth external terminal 27, the fifth external terminal 24, and the seventh external terminal 26. On the opposing long side, two variable capacitance units (iii) and (iv) are similarly arranged, with the sixth, the eighth, the fifth, the seventh, the second, the fourth, the first, and the third external terminal being arranged in the stated order from left.

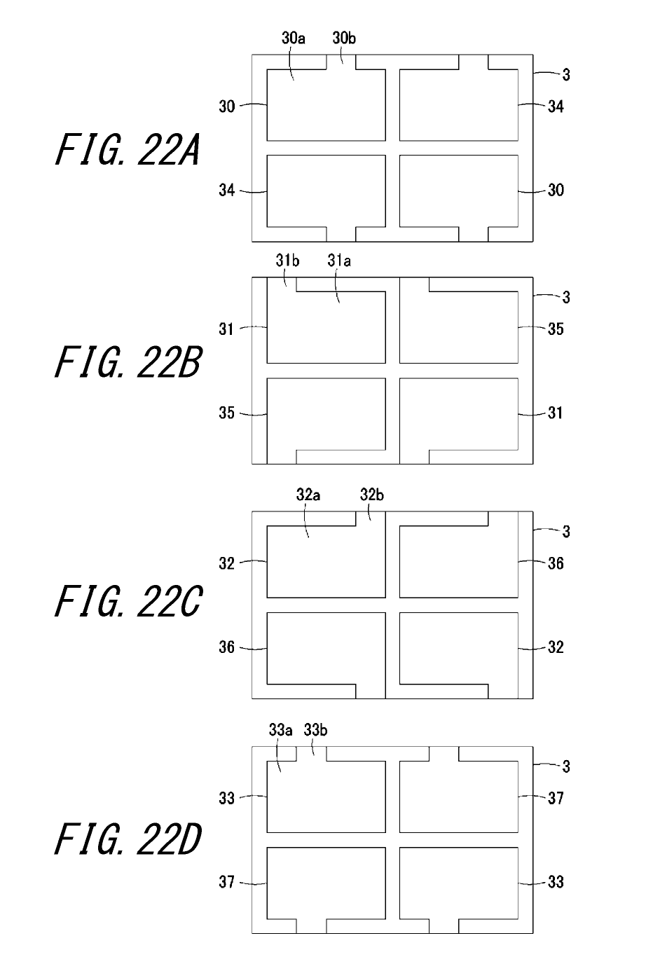

In more detail, as illustrated in FIG. 22, the internal electrodes included in the variable capacitance device 1p are arranged in the positions corresponding to the regions (i) to (iv), with dielectric regions being left for mitigating stresses. To extract four external terminals for internal electrodes laminated in each region, the connection electrodes included in the internal electrodes are arranged and connected in such a manner that prevents the connection electrodes from overlapping in the positions of the electrode bodies. As illustrated in FIG. 22A, the first connection electrode 30b included in the first internal electrode 30 corresponding to the region (i) is arranged in a position shifted to left from the right end of the first electrode body 30a by at least the width of the connection electrode. As illustrated in FIG. 22B, the second connection electrode 31b included in the second internal electrode 31 corresponding to the region (i) is arranged in a position of the left end of the second electrode body 30a. As illustrated in FIG. 22C, the third connection electrode 32b included in the third internal electrode 32 corresponding to the region (i) is arranged in a position of the right end of the third electrode body 32a. As illustrated in FIG. 22D, the fourth connection electrode 33b included in the fourth internal electrode 33 corresponding to the region (i) is arranged in a position shifted to right from the left end of the fourth electrode body 33a by at least the width of the connection electrode.

In the above third embodiment also, of course, additional variable capacitance units may be laminated in the lamination direction to form variable capacitance blocks, and adjacent internal electrodes having an equal potential may be unified.

### 7. Detailed Examples of Contactless Communication System and Contactless Charging System

### [Contactless Communication Device]

<Exemplary Configuration of Contactless Communication Device>

The variable capacitance device 1 according to the embodiments of the present disclosure may be used as resonant capacitors which, together with a resonant coil, configures a resonant circuit. Thus configured resonant circuit may be used in a contactless communication device 140 for contactless communication with another contactless communication device. The contactless communication device 140 is, for example, a reader/writer included in a contactless communication system. The other contactless communication device is, for example, a contactless communication module according to Near Field Communication (NFC) or the like that is embedded in a mobile phone.

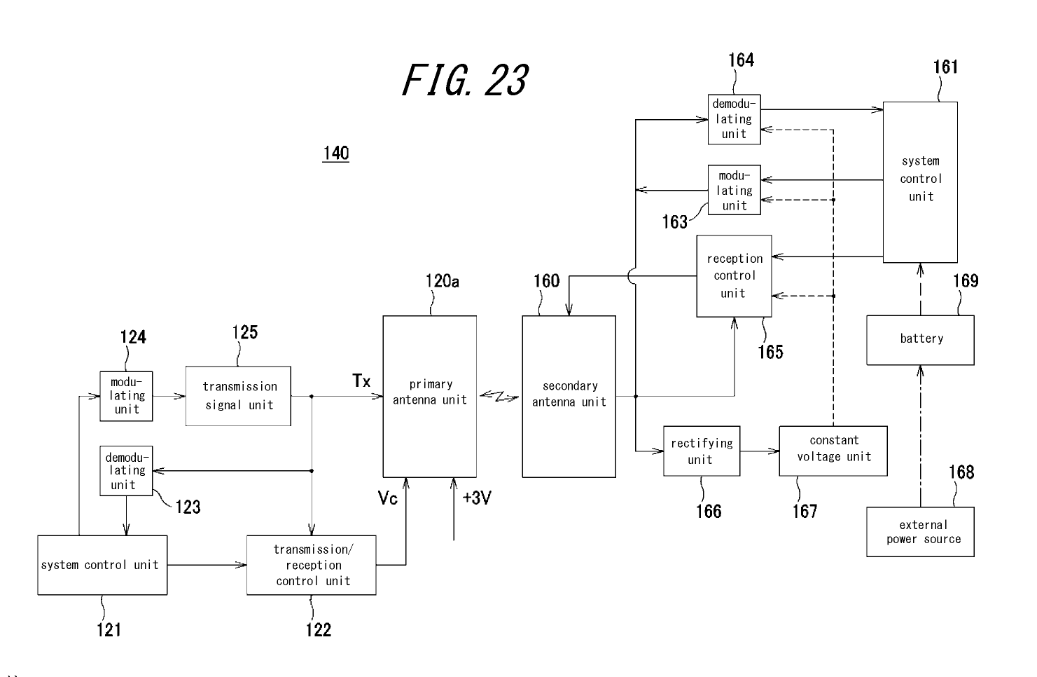

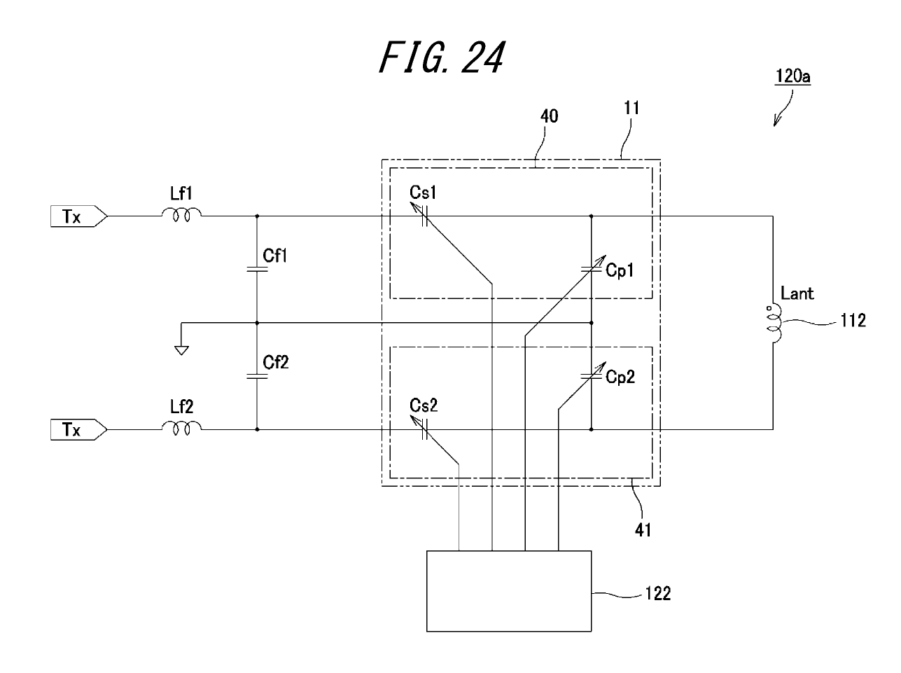

As illustrated in FIGS. 23 and 24, a contactless communication device 140, which serves as a reader/writer included in a contactless communication system, includes a primary antenna unit 120a including a resonant circuit having a variable capacitance circuit 11 and a coil 112. The contactless communication device 140 includes a system control unit 121 configured to control operation of the contactless communication device 140, a modulating unit 124 configured to modulate a transmission signal in accordance with an instruction from the system control unit 121, and a transmission signal unit 125 configured to transmit, to the primary antenna unit 120a, a modulated carrier signal transmitted from the modulating unit 124. Furthermore, the contactless communication device 140 includes a demodulating unit 123 configured to demodulate the modulated carrier signal received from the transmission signal unit 125.

Through the primary antenna unit 120a, the contactless communication device 140 transmits a signal to the contactless communication module including a secondary antenna unit 160. The contactless communication module, which receives the signal by the secondary antenna unit 160, includes a demodulating unit 164 configured to demodulate the received signal, a system control unit 161 configured to control operation of the contactless communication module by using the demodulated signal, and a reception control unit 165 configured to control the condition of reception by regulating parameters of the resonant capacitors and the antenna coil included in the secondary antenna unit 160 based on the received signal. The contactless communication module includes a rectifying unit 166 configured to rectify the signal received by the secondary antenna unit 160 and thus, supplies power to each unit through a constant voltage unit 167 by using the rectified voltage. When the contactless communication module is a portable terminal device, such as a mobile phone, that includes a power source (battery 169), power may be supplied to each unit from the battery 169 and also from an external power source 168, such as an AC adaptor.

FIG. 24 illustrates an exemplary configuration of the primary antenna unit 120a. The variable capacitance circuit 11 used in the primary antenna unit 120a is, for example, the variable capacitance device 1 included in the circuit illustrated in FIG. 2C. The variable capacitance device 1 may be configured as a circuit of CS1 composed of series capacitors C1 and C2, CP1 composed of C3, CS2 composed of series capacitors C4 and C5, and CP2 composed of C6. Thus, the primary antenna unit 120a includes a series-parallel resonant circuit including the variable capacitance capacitors CS1, CP1, CS2, and CP2, and the antenna coil 112.

A transmission/reception control unit 122 controls direct current bias voltages of the capacitors CS1, CP1, CS2, and CP2 of the variable capacitance circuit 11A, thereby setting capacitances thereof to appropriate capacitance values and regulating the resonant frequency together with the resonant coil 112 (Lant).

<Operation of Contactless Communication Device>

Next, a description is given of operation of the contactless communication device 140 including the primary antenna unit 120a using the resonant circuit including the variable capacitance circuit 11.

The contactless communication device 140 performs impedance matching with the primary antenna unit 120a based on a carrier signal that the transmission signal unit 25 transmits, and also regulates the resonant frequency of the resonant circuit in accordance with the condition of reception of the receiver, i. e., the contactless communication module. The modulating unit 124 may use modulation formats and encoding formats, such as Manchester encoding format and an Amplitude Shift Keying (ASK) modulation format, that are typically employed in reader/writers. The carrier frequency is typically 13.56 MHz.

The transmission/reception control unit 122 controls a variable voltage Vc of the primary antenna unit 120a to achieve the impedance matching by monitoring the transmission voltage and the transmission current of the transmitted carrier signal, for impedance regulation.

The signal transmitted from the contactless communication device 140 is received by the secondary antenna unit 160, and the received signal is then demodulated by the demodulating unit 164. The contents of the demodulated signal are determined by the system control unit 161, and the system control unit 161 generates a response signal based on a determination result. Additionally, the reception control unit 165 may also regulate the resonant frequency to optimize the condition of reception by regulating the resonant parameters or the like of the secondary antenna unit 160 based on the amplitude, the voltage phase, and the current phase of the received signal.

The contactless communication module modulates the response signal by the modulating unit 163 and transmits the modulated response signal to the contactless communication device 140 from the secondary antenna unit 160. The contactless communication device 140 receives the response signal by the primary antenna unit 120a and demodulates the received signal by the demodulating unit 123. Based on the demodulated contents, the contactless communication device 140 performs necessary processing by the system control unit 121.

### [Contactless Charging Device]

The resonant circuit 120 using the variable capacitance circuit 11 according to the present disclosure may be incorporated into a contactless charging device (power transmitter) 180 configured to contactlessly charge a secondary battery used in a portable terminal such as a mobile phone. Various contactless charging methods such as an electromagnetic induction method and magnetic resonance may be adopted.

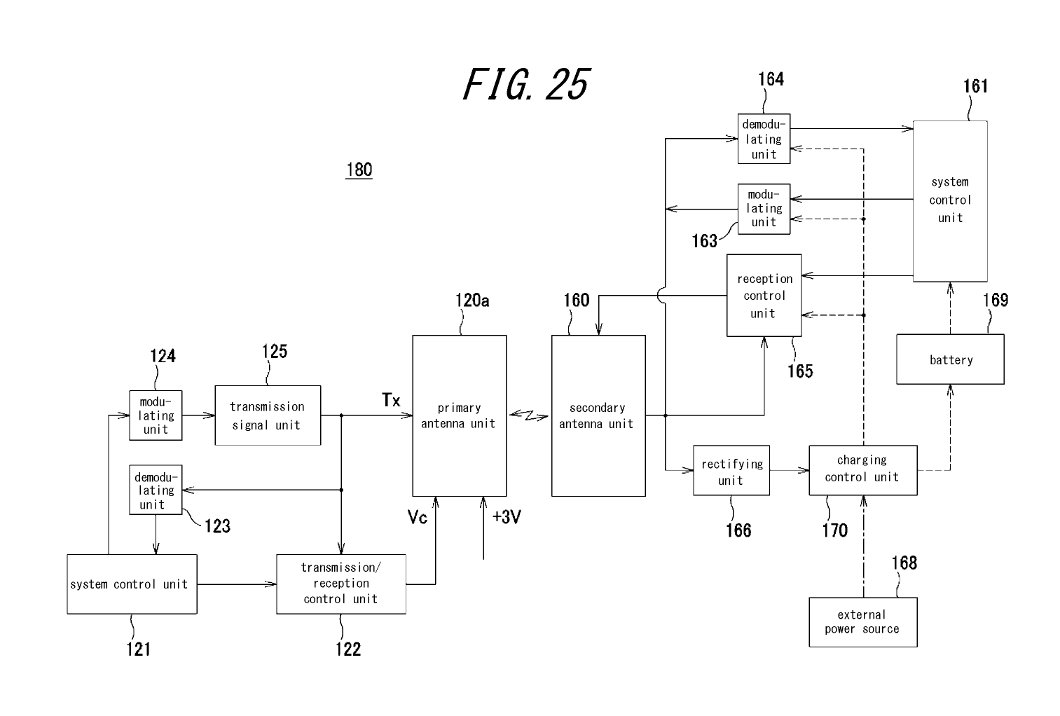

FIG. 25 illustrates an exemplary configuration of a contactless charging system that includes the contactless charging device 180 to which the present disclosure is applied and that also includes a power-receiving device, such as a portable terminal, that is charged and controlled by the contactless charging device 180.

The contactless charging device 180 has substantially the same configuration as the aforementioned contactless communication device 140. The power-receiving device also has substantially the same configuration as the aforementioned contactless communication module. Accordingly, the same reference numerals are used to denote the blocks having the same functions as in the contactless communication device 140 and the contactless communication module illustrated in FIG. 23. Herein, although the carrier frequency used for transmission and reception in the contactless communication device 140 is in most cases 13.56 MHz, the carrier frequency used in the contactless charging device 80 may be in the range from 100 kHz to several hundred kHz.

The contactless charging device 180 performs impedance matching with the primary antenna unit 120a based on a carrier signal that the transmission signal unit 125 transmits, and also regulates the resonant frequency of the resonant circuit in accordance with the condition of reception of the receiver, i. e., the contactless communication module.

The transmission/reception control unit 122 controls a variable voltage Vc of the primary antenna unit 120a to achieve the impedance matching by monitoring the transmission voltage and the transmission current of the transmitted carrier signal, for impedance regulation.

The power-receiving device receives the signal by the secondary antenna unit 160 and rectifies the received signal by the rectifying unit 166. The rectified direct current voltage charges the battery 169 under control of a charging control unit 170. Even when no signal is received by the secondary antenna unit 160, the battery 169 may be charged by driving the charging control unit 170 with use of an external power source 168, such as an AC adaptor.

The signal transmitted from the contactless communication device 140 is received by the secondary antenna unit 160, and the received signal is then demodulated by the demodulating unit 164. The contents of the demodulated signal are determined by the system control unit 161, and the system control unit 161 generates a response signal based on a determination result. Additionally, the reception control unit 165 may also regulate the resonant frequency to optimize the condition of reception by regulating the resonant parameters or the like of the secondary antenna unit 160 based on the amplitude, the voltage phase, and the current phase of the received signal.

### REFERENCE SIGNS LIST

1, 1a to 1p variable capacitance device

2 variable capacitance device body

3 dielectric layer

4 upper dielectric layer

5 lower dielectric layer

20 to 27 first to eighth external terminal

30 to 37 first to eighth internal electrode

30a to 37a first to eighth electrode body

30b to 37b first to eighth connection electrode

40 to 45 first to sixth variable capacitance unit

50 to 51 first to second variable capacitance block

120a primary antenna unit

121 system control unit

122 transmission/reception control unit

123 demodulating unit

124 modulating unit

125 transmission signal unit

140 contactless communication device

160 secondary antenna unit

161 system control unit

163 demodulating unit

164 modulating unit

165 reception control unit

166 rectifying unit

167 constant voltage unit

168 external power source

169 battery

170 charging control unit

180 contactless charging device

1. A capacitance device, comprising:
two or more capacitance blocks each including one or more capacitance units, each capacitance unit including: a capacitance element body, which includes two or more capacitors formed by dielectric layers and three or more internal electrodes laminated via the dielectric layers, the three or more internal electrodes each having an electrode body forming a capacitance, centers of gravity of the electrode bodies being aligned on an axis formed by a straight line extending in a direction in which the internal electrodes are laminated, and the two or more capacitors being connected in series in the lamination direction; and external terminals formed on lateral surfaces of the capacitance element body and electrically connected to the electrode bodies forming the capacitances, wherein
the one or more capacitance units included in each capacitance block are arranged on the axis,
the axes of the two or more capacitance blocks are arranged in parallel with each other, and
a current flows in opposite directions in any two adjacent capacitance units, and wherein
the internal electrodes laminated on the dielectric layers to form the capacitors in one of the two or more capacitance blocks are arranged on same planes as those in another one of the two or more capacitance blocks located adjacent to the one of the two or more capacitance blocks, and
in any two corresponding capacitance units included in the one of the two or more capacitance blocks and in the other one of the two or more capacitance blocks located adjacent to the one of the two or more capacitance blocks, a current flowing along one of the planes on which one of the three or more internal electrodes laminated on an uppermost layer is arranged and along another one of the planes on which another one of the three or more internal electrodes laminated on a lowermost layer is arranged flows in opposite directions.

2. (canceled)

3. (canceled)

4. The capacitance device of claim 1, wherein the three or more internal electrodes each have the electrode body and a connection electrode configured to electrically connect the electrode body to a corresponding one of the external terminals, the laminated electrode bodies having a same shape.

5. The capacitance device of claim 1, wherein the one or more capacitance units included in each of the two or more capacitance blocks are connected in parallel.

6. The capacitance device of claim 5, wherein the two or more capacitance blocks are connected in series.

7. The capacitance device of claim 1, wherein one of the three or more internal electrodes laminated on an uppermost layer in one of the one or more capacitance units included in the capacitance block has a potential that is set in advance to be equal to that of one of the three or more internal electrodes laminated on a lowermost layer in another one of the one or more capacitance units located adjacent to the one of the one or more capacitance units included in the capacitance block.

8. The capacitance device of claim 1, wherein one of the internal electrodes laminated on an uppermost layer or a lowermost layer in the one of the two or more capacitance blocks has a potential that is set in advance to be equal to that of one of the internal electrodes laminated on an uppermost layer or a lowermost layer in the other one of the two or more capacitance blocks located adjacent to the one of the two or more capacitance blocks.

9. A resonant circuit, comprising
(i) a capacitance device comprising two or more capacitance blocks each including one or more capacitance units, each capacitance unit including: a capacitance element body, which includes two or more capacitors formed by dielectric layers and three or more internal electrodes laminated via the dielectric layers, the three or more internal electrodes each having an electrode body forming a capacitance, centers of gravity of the electrode bodies being aligned on an axis formed by a straight line extending in a direction in which the internal electrodes are laminated, and the two or more capacitors being connected in series in the lamination direction; and external terminals formed on lateral surfaces of the capacitance element body and electrically connected to the electrode bodies forming the capacitances, wherein
the one or more capacitance units included in each capacitance block are arranged on the axis,
the axes of the two or more capacitance blocks are arranged in parallel with each other, and
a current flows in opposite directions in any two adjacent capacitance units, and wherein
the internal electrodes laminated on the dielectric layers to form the capacitors in one of the two or more capacitance blocks are arranged on same planes as those in another one of the two or more capacitance blocks located adjacent to the one of the two or more capacitance blocks, and
in any two corresponding capacitance units included in the one of the two or more capacitance blocks and in the other one of the two or more capacitance blocks located adjacent to the one of the two or more capacitance blocks, a current flowing along one of the planes on which one of the three or more internal electrodes laminated on an uppermost layer is arranged and along another one of the planes on which another one of the three or more internal electrodes laminated on a lowermost layer is arranged flows in opposite directions, and
(ii) a resonant coil connected to the capacitance device.

10. (canceled)

11. (canceled)

12. The resonant circuit of claim 9, wherein the three or more internal electrodes each have the electrode body and a connection electrode configured to electrically connect the electrode body to a corresponding one of the external terminals, the laminated electrode bodies having a same shape.

13. The resonant circuit of claim 9, wherein the one or more capacitance units included in each of the two or more capacitance blocks are connected in parallel.

14. The resonant circuit of claim 13, wherein the two or more capacitance blocks are connected in series.

15. The resonant circuit of claim 9, wherein one of the three or more internal electrodes laminated on an uppermost layer in one of the one or more capacitance units included in the capacitance block has a potential that is set in advance to be equal to that of one of the three or more internal electrodes laminated on a lowermost layer in another one of the one or more capacitance units located adjacent to the one of the one or more capacitance units included in the capacitance block.

16. The resonant circuit of claim 9, wherein one of the internal electrodes laminated on an uppermost layer or a lowermost layer in the one of the two or more capacitance blocks has a potential that is set in advance to be equal to that of one of the internal electrodes laminated on an uppermost layer or a lowermost layer in the other one of the two or more capacitance blocks located adjacent to the one of the two or more capacitance blocks.

17. An electronic apparatus, comprising:
a capacitance device comprising two or more capacitance blocks each including one or more capacitance units, each capacitance unit including: a capacitance element body, which includes two or more capacitors formed by dielectric layers and three or more internal electrodes laminated via the dielectric layers, the three or more internal electrodes each having an electrode body forming a capacitance, centers of gravity of the electrode bodies being aligned on an axis formed by a straight line extending in a direction in which the internal electrodes are laminated, and the two or more capacitors being connected in series in the lamination direction; and external terminals formed on lateral surfaces of the capacitance element body and electrically connected to the electrode bodies forming the capacitances, wherein
the one or more capacitance units included in each capacitance block are arranged on the axis,
the axes of the two or more capacitance blocks are arranged in parallel with each other, and
a current flows in opposite directions in any two adjacent capacitance units, and wherein
the internal electrodes laminated on the dielectric layers to form the capacitors in one of the two or more capacitance blocks are arranged on same planes as those in another one of the two or more capacitance blocks located adjacent to the one of the two or more capacitance blocks, and
in any two corresponding capacitance units included in the one of the two or more capacitance blocks and in the other one of the two or more capacitance blocks located adjacent to the one of the two or more capacitance blocks, a current flowing along one of the planes on which one of the three or more internal electrodes laminated on an uppermost layer is arranged and along another one of the planes on which another one of the three or more internal electrodes laminated on a lowermost layer is arranged flows in opposite directions.
